(19) United States
(12) Patent Application Publication
(10) Pub. No.: US 2022/0155682 A1
(43) Pub. Date: May 19, 2022

(54) FILM FORMING MATERIAL FOR LITHOGRAPHY, COMPOSITION FOR FILM FORMATION FOR LITHOGRAPHY, UNDERLAYER FILM FOR LITHOGRAPHY, METHOD FOR FORMING PATTERN, AND PURIFICATION METHOD

(71) Applicant: Mitsubishi Gas Chemical Company, Inc., Tokyo (JP)

(72) Inventors: Junya HORIUCHI, Kanagawa (JP); Takashi MAKINOSHIMA, Kanagawa (JP); Masatoshi ECHIGO, Tokyo (JP)

(21) Appl. No.: 17/439,734

(22) PCT Filed: Mar. 18, 2020
(86) PCT No.: PCT/JP2020/011944

§ 371 Date: Sep. 15, 2021

(30) Foreign Application Priority Data
Mar. 19, 2019 (JP) 2019-051506

(51) Int. Cl. G03F 7/038; G03F 7/11; C08G 73/18; G03F 7/20; G03F 7/40; G03F 7/32

(52) U.S. Cl. CPC G03F 7/0382; G03F 7/11; G03F 7/325; G03F 7/2004; G03F 7/40; C08G 73/18

(57) ABSTRACT

A film forming material for lithography, including a resin having a polybenzimidazole structure represented by the following formula (1).

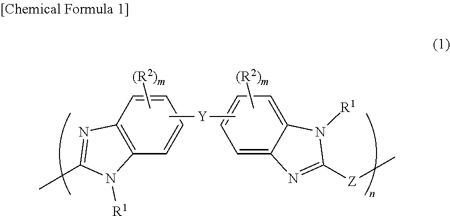

Y and Z are each a single bond, a divalent linking group comprising a chalcogen atom, or a divalent linking group derived from a compound selected from an aromatic compound and the like, R¹ is independently a hydrogen atom, or a substituent T selected from the group consisting of a specified alkyl group and the like, a halogen atom, a nitro group, an amino group, a cyano group, a carboxylic acid group, a thiol group and a hydroxy group, wherein the alkyl group and the like each optionally include an ether bond, a ketone bond, an ester bond or a urethane bond, R² is a substituent T, m is an integer of 0 to 3, and n is an integer of 1 to 10000.

### TECHNICAL FIELD

The present invention relates to a film forming material for lithography, a composition for film formation for lithography, containing the material, an underlayer film for lithography, formed by using the composition, and a method for forming a pattern (for example, a resist pattern method or a circuit pattern method), using the composition.

### BACKGROUND ART

Fine processing by lithography using photoresist materials is performed in production of semiconductor devices. In recent years, further refining by pattern rules has been demanded along with higher integration and higher speed of LSI. Lithography using light exposure, currently used as general-purpose technology, is approaching the limit of essential resolution derived from the wavelength of a light source.

Light sources for lithography, for use in resist pattern formation, are shortened in wavelengths from KrF excimer laser (248 nm) to ArF excimer laser (193 nm). However, if refining of resist patterns progress, the problem about resolution or the problem of resist pattern collapse after development is caused and thus resists are demanded to be thinned. In this regard, if resists are simply thinned, resist patterns have a difficulty in obtaining thicknesses sufficient for substrate processing. Thus, a process has been required which involves producing not only a resist pattern, but also a resist underlayer film between a resist and a semiconductor substrate to be processed, and allowing the resist underlayer film to also have a function as a mask in substrate processing.

Various films are currently known as resist underlayer films for use in such a process. For example, an underlayer film forming material for multi-layer resist process, the material containing a resin component having at least a substituent which generates a sulfonic acid residue by elimination of a terminal group due to application of predetermined energy and a solvent, is proposed as one which realizes a resist underlayer film for lithography, the film having a dry etching rate selectivity close to that of a resist, unlike a conventional resist underlayer film high in etching rate (see PTL 1.). Moreover, a resist underlayer film material including a polymer having a specified repeating unit is proposed as one which realizes a resist underlayer film for lithography, having low dry etching rate selectivity as compared with a resist (see PTL 2.). Furthermore, a resist underlayer film material including a polymer obtained by copolymerizing an acenaphthylene repeating unit and a repeating unit having a substituted or non-substituted hydroxy group is proposed as one which realizes a resist underlayer film for lithography, having low dry etching rate selectivity as compared with a semiconductor substrate (see PTL 3.).

In this regard, such a resist underlayer film of a material having high etching resistance, which is well-known, is an amorphous carbon underlayer film formed by CVD using a methane gas, an ethane gas, an acetylene gas, or the like as a raw material.

The present inventors have proposed, as a material which not only is excellent in optical characteristics and etching resistance, but also is soluble in a solvent and can be applied to a wet process, a composition for underlayer film formation for lithography, the composition containing a naphthalene formaldehyde polymer having a specified constituent unit and an organic solvent (see Patent Literatures 4 and 5.).

There are known methods for forming intermediate layers for use in resist underlayer film formation in three-layer processes, for example, a method for forming a silicon nitride film (see PTL 6.) and a method for forming a silicon nitride film by CVD (see PTL 7.). There are also known intermediate layer materials for three-layer processes, for example, materials each including a silsesquioxane-based silicon compound (see Patent Literatures 8 and 9.).

### CITATION LIST

### Patent Literature

PTL 1: Japanese Patent Laid-Open No. 2004-177668

PTL 2: Japanese Patent Laid-Open No. 2004-271838

PTL 3: Japanese Patent Laid-Open No. 2005-250434

PTL 4: International Publication No. WO 2009/072465

PTL 5: International Publication No. WO 2011/034062

PTL 6: Japanese Patent Laid-Open No. 2002-334869

PTL 7: International Publication No. WO 2004/066377

PTL 8: Japanese Patent Laid-Open No. 2007-226170

PTL 9: Japanese Patent Laid-Open No. 2007-226204

### SUMMARY OF INVENTION

### Technical Problem

Although many film forming materials for lithography have been conventionally proposed as described above, there has not been any material which satisfies not only a high solvent-solubility which can allow for application to a wet process such as a spin coating method or screen printing, but also both heat resistance and etching resistance at high levels, and there is a demand for development of a novel material.

The present invention has been made in view of the above problems, and an object thereof is to provide a film forming material for lithography, which can be applied to a wet process and which is useful for forming a film for lithography, the film being excellent in heat resistance and etching resistance, and a composition for film formation for lithography, containing the material, as well as an underlayer film for lithography and a method for forming a pattern, each using the composition.

### Solution to Problem

The present inventors have made intensive studies in order to solve the above problems, and as a result, have found that the above problems can be solved by using a compound having a specified structure, leading to completion of the present invention. Specifically, the present invention is as follows.

[1]

A film forming material for lithography, including a resin having a polybenzimidazole structure represented by formula (1) described below.

[2]

The film forming material for lithography according to [1], wherein R¹ in formula (1) is a group other than a hydrogen atom.

[3]

The film forming material for lithography according to [1] or [2], wherein Y in formula (1) is a single bond, —O—, —S—, —CH₂—, —C(CH₃)₂—, —CO—, —SO₂—, —C(CF₃)₂—, —CONH— or —COO—.

[4]

The film forming material for lithography according to [3], wherein Y in formula (1) is a single bond.

[5]

The film forming material for lithography according to any one of [1] to [4], wherein the film for lithography is an underlayer film for lithography.

[6]

A composition for film formation for lithography, containing the film forming material for lithography according to any one of [1] to [5], and a solvent.

[7]

The composition for film formation for lithography according to [6], further containing a crosslinking agent.

[8]

The composition for film formation for lithography according to [7], further containing a crosslinking promoting agent.

[9]

The composition for film formation for lithography according to any one of [6] to [8], further containing a radical polymerization initiator.

[10]

The composition for film formation for lithography according to any one of [6] to [9], further containing an acid generating agent.

[11]

An underlayer film for lithography, formed using the composition for film formation for lithography according to any one of [6] to [10].

[12]

A method for forming a resist pattern, including

a step of forming an underlayer film on a substrate using the composition for film formation for lithography according to any one of [6] to [10],

a step of forming at least one photoresist layer on the underlayer film, and

a step of irradiating a predetermined region of the photoresist layer with radiation for development.

[13]

A method for forming a pattern, including

a step of forming an underlayer film on a substrate using the composition for film formation for lithography according to any one of [6] to [10],

a step of forming an intermediate layer film on the underlayer film using a silicon atom-containing resist intermediate layer film material,

a step of forming at least one photoresist layer on the intermediate layer film,

a step of irradiating a predetermined region of the photoresist layer with radiation for development to thereby form a resist pattern,

a step of etching the intermediate layer film with the resist pattern as a mask,

a step of etching the underlayer film with an intermediate layer film pattern obtained in the above step, as an etching mask, and

a step of etching the substrate with an underlayer film pattern obtained in the above step, as an etching mask, to thereby form a pattern on the substrate.

[14]

A method for purifying the film forming material for lithography according to any one of [1] to [5], including

a step of dissolving the film forming material for lithography in a solvent to thereby obtain an organic phase, and

a first extraction step of contacting the organic phase and an acidic aqueous solution to thereby extract impurities in the film forming material for lithography, wherein

the solvent includes a solvent that does not mix with water at any ratio.

[15]

A resin having a polybenzimidazole structure represented by formula (1′) described below.

[16]

A method for producing a film for lithography, including

a step of preparing a composition including a resin having a polybenzimidazole structure, and

a step of placing the composition on a substrate and baking the resultant at 300 to 900° C.

### Advantageous Effects of Invention

According to the present invention, there can be provided a film forming material for lithography, which can be applied to a wet process and which is useful for forming a film for lithography, the film being excellent in heat resistance and etching resistance, and a composition for film formation for lithography, containing the material, as well as an underlayer film for lithography and a method for forming a pattern, each using the composition.

### DESCRIPTION OF EMBODIMENTS

Hereinafter, each embodiment of the present invention is described. The following embodiments are illustrative for describing the present invention, and the present invention is not limited only to such embodiments. “X to Y” in the present invention includes X and Y as end values.

The “composition for film formation for lithography” means a material which can be formed into a film for lithography on a substrate, which includes a resin having a polybenzimidazole structure and a solvent, and which has fluidity capable of allowing for film formation.

The “film forming material for lithography” means a material for constituting a film for lithography, which is a resin composition including, as a resin, only a resin having a polybenzimidazole structure, in one aspect, or including, as a resin, a resin having a polybenzimidazole structure and, as any resin other than the resin, a resin capable of forming a matrix, in another aspect.

[Film Forming Material for Lithography]

<Resin>

A film forming material for lithography according to one embodiment of the present invention contains a resin having a polybenzimidazole structure. The resin having a poly benzimidazole structure refers to a resin (homopolymer) whose repeating unit includes only a unit having a benzimidazole backbone (hereinafter, also referred to as “BI unit”) or a resin (copolymer) whose repeating unit includes a BI unit and any other unit. If the amount of the BI unit is large, the material is enhanced in heat resistance. The BI unit in the latter resin, from this viewpoint, preferably has a lower limit of 50 mol % or more, more preferably 75 mol % or more, further preferably 90 mol % or more, and preferably has an upper limit of 99 mol % or less, more preferably 95 mol % or less.

The content of the resin having a polybenzimidazole structure in the film forming material for lithography of the present embodiment is preferably 5 to 100 mass %, more preferably 51 to 100 mass %, further preferably 60 to 100 mass %, still further preferably 70 to 100 mass %, particularly preferably 80 to 100 mass %, from the viewpoint of heat resistance. Any resin component other than the resin having a poly benzimidazole structure in the film forming material is not particularly limited, and examples thereof include a high heat-resistant polymer such as engineering plastic.

The resin having a polybenzimidazole structure encompasses an oligomer and a polymer each having a benzimidazole backbone in a side chain, and an oligomer and a polymer each having a benzimidazole backbone in a main chain.

The resin having a polybenzimidazole structure, which can be used in the film forming material for lithography of the present embodiment, can have any intrinsic viscosity in a wide range depending on, for example, the structure and the molecular weight thereof, and the number average molecular weight of the resin having a polybenzimidazole structure in the present invention is generally 2,000 to 1,000000, preferably 2,000 to 300,000, more preferably 5,000 to 100,000.

A preferable polybenzimidazole structure in the present invention is represented by the following formula.

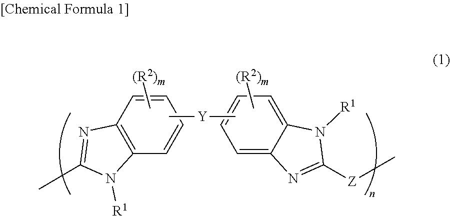

In formula (1), n is the number of repeating units, and is an integer of 1 to 10000, preferably 1 to 100 from the viewpoints of coatability by a wet process and thickness control. Y and Z are each a single bond, a divalent linking group including a chalcogen atom, or a divalent linking group derived from a compound selected from the group consisting of an aromatic compound; a linear, branched or cyclic aliphatic compound; and a heterocyclic compound.

The chalcogen atom means any atom belonging to group 16 in the periodic table, and is preferably an oxygen atom or a sulfur atom in terms of availability or the like of a raw material. Examples of the divalent linking group including a chalcogen atom include —O—, —S—, —CO—, —SO₂—, —CONH— or —COO—.

The divalent linking group derived from an aromatic compound is a group obtained by removing two hydrogen atoms from the compound. The compound is a monocyclic aromatic compound or a polycyclic aromatic compound each having 6 to 20, preferably 6 to 15 carbon atoms. The polycyclic aromatic compound in the present invention encompasses a polycyclic compound where aromatic rings are fused and a polycyclic compound where an aromatic ring and an alicyclic ring are fused. Examples of the group include a diphenylene group, a naphthylene group, and a trimethylindanylene group.

The divalent linking group derived from a linear, branched or cyclic aliphatic compound is a group obtained by removing two hydrogen atoms from the compound, and optionally includes a halogen atom. The compound encompasses a saturated hydrocarbon and an unsaturated hydrocarbon each having 1 to 10 carbon atoms. Examples of the group include a methylene group, —CH₂—, —C(CH₃)₂—, —C(CF₃)₂—, an amylene group, an octamethylene group, and a cyclohexenyl group.

The divalent linking group derived from a heterocyclic compound is a group obtained by removing two hydrogen atoms from the compound. The compound is a monocyclic or polycyclic, heteroatom-containing aromatic compound having 6 to 20, preferably 6 to 15 carbon atoms. Examples of the heteroatom include an oxygen atom, a sulfur atom, and a nitrogen atom. Examples of the group include a furylene group.

Y is preferably a single bond, —O—, —S—, —CH₂—, —C(CH₃)₂—, —CO—, —SO₂—, —C(CF₃)₂—, —CONH— or —COO—, more preferably a single bond, from the viewpoint of availability or the like of a raw material. Accordingly, in one aspect, the above structural formula is preferably represented by formula (2), more preferably represented by formula (3).

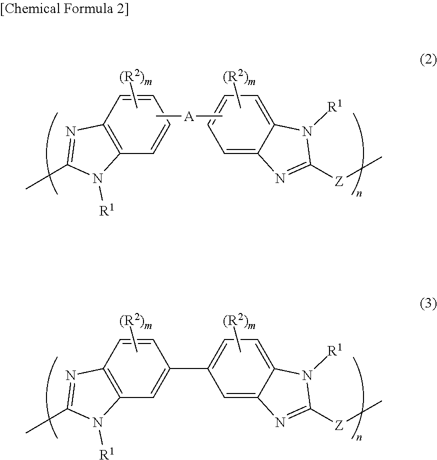

In formula (2), A is a single bond, —O—, —S—, —CH₂—, —C(CH₃)₂—, —CO—, —SO₃—, —C(CF₃)₃—, —CONH— or —COO—.

R¹ in the formula is each independently a hydrogen atom or a substituent T. The substituent T is selected from the group consisting of an alkyl group having 1 to 30 carbon atoms and optionally having a substituent, an aryl group having 6 to 40 carbon atoms and optionally having a substituent, an aralkyl group having 7 to 40 carbon atoms and optionally having a substituent, an alkenyl group having 2 to 30 carbon atoms and optionally having a substituent, an alkynyl group having 2 to 30 carbon atoms and optionally having a substituent, an arylalkenyl group having 7 to 40 carbon atoms and optionally having a substituent, an alkoxy group having 1 to 30 carbon atoms and optionally having a substituent, a halogen atom, a nitro group, an amino group, a cyano group, a carboxylic acid group, a thiol group and a hydroxy group. The aryl group, the aralkyl group, the alkenyl group, the alkynyl group, and the arylalkenyl group each optionally include an ether bond, a ketone bond, an ester bond or a urethane bond. Each R² is independently a substituent T.

The alkyl group having 1 to 30 carbon atoms is not particularly limited, and examples thereof include a methyl group, an ethyl group, a n-propyl group, an i-propyl group, a n-butyl group, an i-butyl group, a t-butyl group, a cyclopropyl group, and a cyclobutyl group. In a case where the alkyl group having 1 to 30 carbon atoms has a substituent, at least one substituent selected from the group consisting of a halogen atom, a nitro group, an amino group, a thiol group, a hydroxy group, an epoxy group, and a group obtained by substituting a hydrogen atom of a hydroxy group with an acid dissociation group is preferably bound to the alkyl group.

The acid dissociation group refers to a group capable of generating an alkali-soluble group by cleavage in the presence of an acid. The alkali-soluble group is not particularly limited, and examples thereof include a phenolic hydroxy group, a carboxyl group, a sulfonic acid group, and a hexafluoroisopropanol group, and in particular, a phenolic hydroxy group and a carboxyl group are preferable, and a phenolic hydroxy group is more preferable, from the viewpoint of availability of a reagent introduced. The acid dissociation group preferably has the property of allowing a cleavage reaction to occur in a chain manner in the presence of an acid in order to enable a pattern high in sensitivity and high in resolution to be formed. The acid dissociation group is not particularly limited, and the group here used can be appropriately selected from those proposed with respect to a hydroxystyrene resin and a (meth)acrylic resin which are for use in a chemical amplification type resist composition for KrF or ArF. Specific examples of the acid dissociation group can include any group described in International Publication No. WO 2016/158168. The acid dissociation group is suitably, for example, a 1-substituted ethyl group, a 1-substituted-n-propyl group, a 1-branched alkyl group, a silyl group, acyl group, a 1-substituted alkoxymethyl group, a cyclic ether group, an alkoxycarbonyl group, and an alkoxycarbonylalkyl group which each have the property of being dissociated by an acid.

The substituent which is optionally in the alkyl group having 1 to 30 carbon atoms, other than those described above, may be a cyano group, an acyl group, an alkoxycarbonyl group, an alkyloyloxy group, an aryloyloxy group, or an alkylsilyl group.

The aryl group having 6 to 40 carbon atoms is not particularly limited, and examples thereof include a phenyl group, a naphthalene group, and a biphenyl group. In a case where the aryl group having 6 to 40 carbon atoms has a substituent, one or more of the above substituents is preferably bound to the aryl group.

The aralkyl group having 7 to 40 carbon atoms is not particularly limited, and examples thereof include a benzyl group, a naphthylmethyl group, and a biphenylmethyl group. In a case where the aralkyl group having 7 to 40 carbon atoms has a substituent, at least one substituent selected from the above group of substituents is preferably bound to the aralkyl group.

The alkenyl group means an aliphatic hydrocarbon group having a carbon-carbon double bond, and is, for example, a group represented by the following formula.

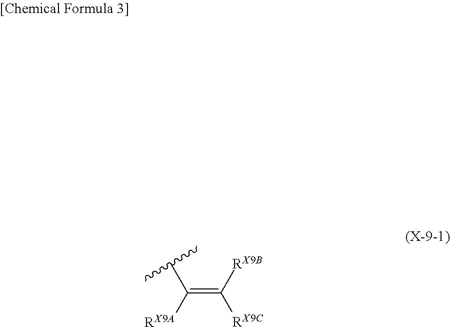

In formula (X-9-1). R^{X9A}, R^{X9B} and R^{X9C} are each independently a hydrogen atom or a monovalent hydrocarbon group having 1 to 20 carbon atoms.

The alkenyl group having 2 to 30 carbon atoms is not particularly limited, and examples thereof include a propenyl group, a butenyl group, a group having an allyl group, a group having a (meth)acryloyl group, a group having an epoxy (meth)acryloyl group, and a group having a urethane(meth)acryloyl group. In a case where the alkenyl group having 2 to 30 carbon atoms has a substituent, one or more of the above substituents is preferably bound to the alkenyl group.

The group having an allyl group is not particularly limited, and examples thereof include a group represented by the following formula (X-1). In formula (X-1), n^{X1} is an integer of 1 to 5.

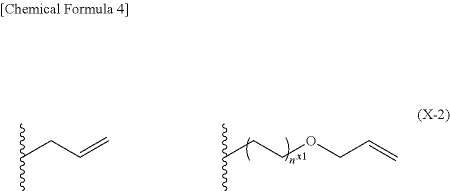

The group having a (meth)acryloyl group is not particularly limited, and examples thereof include a group represented by the following formula (X-2). In formula (X-2), n^{X2} is an integer of 1 to 5, and R^{X} is a hydrogen atom or a methyl group.

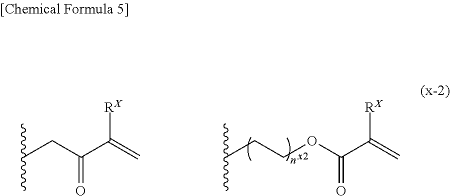

The epoxy (meth)acryloyl group refers to a group generated by a reaction of an epoxy group and (meth)acrylate. The group having an epoxy (meth)acryloyl group is not particularly limited, and examples thereof include a group represented by the following formula (X-3). In formula (X-3), n^{x3} is an integer of 0 to 5, and R^{X} is a hydrogen atom or a methyl group.

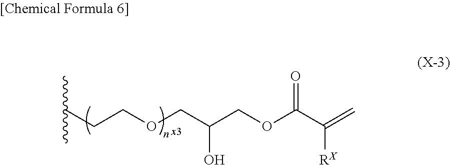

The group having a urethane(meth)acryloyl group is not particularly limited, and examples thereof include a group represented by the following formula (X-4). In formula (X-4), n^{x4} is an integer of 0 to 5, s is an integer of 0 to 3, and R^{X} is a hydrogen atom or a methyl group.

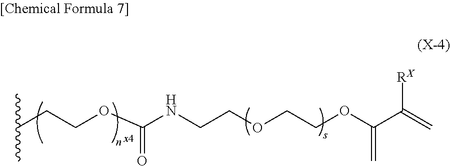

The alkynyl group means an aliphatic hydrocarbon group having a carbon-carbon triple bond, is not particularly limited, and is, for example, a group represented by the following formula.

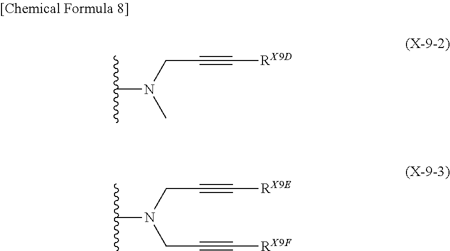

In formulae (X-9-2) and (X-9-3), R^{X9D}, R^{X9E} and R^{X9F} are each independently a hydrogen atom or a monovalent hydrocarbon group having 1 to 20 carbon atoms.

The alkynyl group having 2 to 30 carbon atoms is not particularly limited, and examples thereof include a propynyl group, a butynyl group, and a group represented by the following formula (X-8). In formula (X-8), n^{x8} is an integer of 1 to 5.

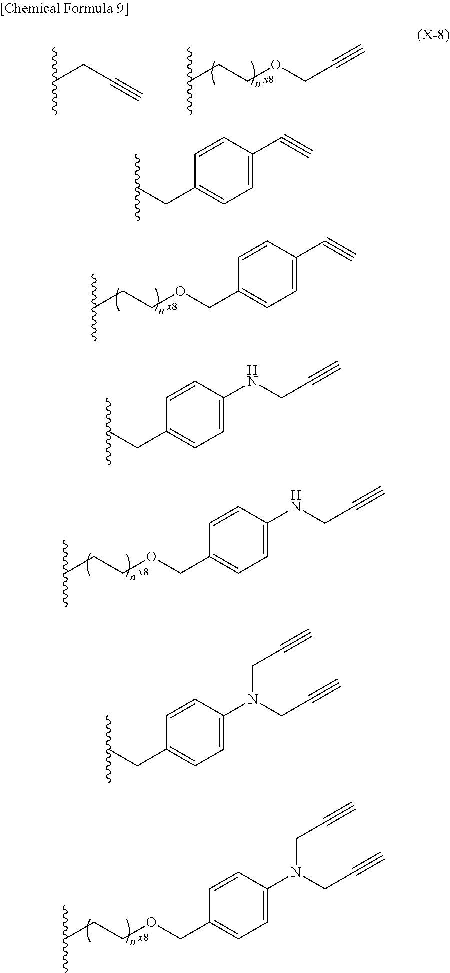

In a case where the alkynyl group having 2 to 30 carbon atoms has a substituent, one or more of the above substituents is preferably bound to the alkynyl group.

The arylalkenyl group having 7 to 40 carbon atoms and optionally having a substituent is not particularly limited, and examples thereof include a vinylphenyl group. In a case where the arylalkenyl group having 7 to 40 carbon atoms has a substituent, one or more of the above substituents is preferably bound to the arylalkenyl group.

The alkoxy group having 1 to 30 carbon atoms is not particularly limited, and examples thereof include a methoxy group, an ethoxy group, a propoxy group, a cyclohexyloxy group, a phenoxy group, a naphthaleneoxy group, and a biphenyloxy group. In a case where the alkoxy group having 1 to 30 carbon atoms has a substituent, one or more of the above substituents is preferably bound to the alkoxy group.

Z is preferably at least one group selected from the group consisting of an aromatic group having 6 to 20 carbon atoms and optionally having a substituent, an aliphatic group having 1 to 20 carbon atoms and optionally having a substituent, and an alicyclic group having 3 to 12 carbon atoms and optionally having a substituent, from the viewpoint of availability of a raw material. Z is more preferably an aromatic group having 6 to 20 carbon atoms or an alicyclic group having 3 to 12 carbon atoms.

Examples of such a group include the following:

phenylene groups such as a 1,4-phenylene group and a 1,3-phenylene group:

divalent fused polycyclic aromatic groups, for example, naphthalenediyl groups such as a naphthalen-1,4-diyl group, a naphthalen-1,5-diyl group, a naphthalen-2,6-diyl group and a naphthalen-2,7-diyl group, anthracenediyl groups such as an anthracen-1,4-diyl group, an anthracen-1,5-diyl group, an anthracen-1,8-diyl group, an anthracen-1,10-diyl group and an anthracen-2,6-diyl group, and phenanthrenediyl groups such as a phenanthren-1,8-diyl group, a phenanthren-2,7-diyl group, a phenanthren-3,6-diyl group and a phenanthren-9,10-diyl group;

divalent cyclic hydrocarbon groups such as a cyclopropan-1,2-diyl group, a cyclobutan-1,2-diyl group, a cyclobutan-1,3-diyl group, a cyclopentan-1,2-diyl group, a cyclopentan-1,3-diyl group, a cyclohexan-1,4-diyl group, a decalin-1,4-diyl group, a decalin-1,5-diyl group, a decalin-2,6-diyl group, a decalin-2,7-diyl group, a norbornan-1,4-diyl group, a norbornan-2,3-diyl group and a norbornan-2,7-diyl group, and

divalent spirohydrocarbon groups such as a spiro[3,3]heptan-2,6-diyl group, a spiro[4,4]nonan-2,7-diyl group, a spiro[5,5]undecan-3,9-diyl group and a tetracyclododecen-2,3-diyl group.

In particular, a 1,4-phenylene group, a naphthalen-2,6-diyl group, an anthracen-1,4-diyl group, an anthracen-1,5-diyl group, a cyclohexan-1,4-diyl group, a decalin-1,4-diyl group, a decalin-2,6-diyl group, a norbornan-2,3-diyl group, or a tetracyclododecen-2,3-diyl is preferable, and a 1,4-phenylene group, a naphthalen-2,6-diyl group, a decalin-2,6-diyl group, or a tetracyclododecen-2,3-diyl group is more preferable. Such a group may be adopted singly or in combinations of two or more kinds thereof.

Specific examples of such polybenzimidazole include the following: poly-2,2′-(m-phenylene)-5,5′-dibenzimidazole, poly-2,2′-(diphenylene-2,2′″)-5,5′-dibenzimidazole, poly-2,2′-(diphenylene-4″,4′″)-5,5′-dibenzimidazole, poly-2,2′-(1″,1″,3″-trimethylindanylene)-3″,5″-p-phenylene-5,5′-dibenzimidazole, a 2,2′-(m-phenylene)-5,5′-dibenzimidazole/2,2′-(1″,1″,3″-trimethylindanylene)-3″,5″-p-phenylene-5,5′-dibenzimidazole copolymer, a 2,2′-(m-phenylene)-5,5′-dibenzimidazole/2,2′-(diphenylene-2″,2′″)-5,5′-dibenzimidazole copolymer, poly-2,2′-(furylene-2″,5″)-5,5′-dibenzimidazole, poly-2,2′-(naphthalen-1″,6″)-5,5′-dibenzimidazole, poly-2,2′-(naphthalen-2″,6″)-5,5′-dibenzimidazole, poly-2,2′-amylene-5,5′-dibenzimidazole, poly-2,2′-octamethylene-5,5′-dibenzimidazole, poly-2,2′-cyclohexenyl-5,5′-dibenzimidazole, poly-2,2′-(m-phenylene)-5,5′-di(benzimidazole)ether, poly-2,2′-(m-phenylene)-5,5′-di(benzimidazole)sulfide, poly-2,2′-(m-phenylene)-5,5′-di(benzimidazole)sulfone, poly-2,2′-(m-phenylene)-5,5′-di(benzimidazole)methane, poly-2,2′-(m-phenylene)-5,5′-di(benzimidazole)propane 2,2, and poly-ethylene-1,2,2,2″-(m-phenylene)-5,5′-di(benzimidazole)ethylene-1.2.

m is the number of R²(s), and is an integer of 0 to 3. R² preferably has no bulkiness from the viewpoints of availability, ease of production, and the like of a raw material. Accordingly, m is preferably 0. In a case where m is not 0, R² is preferably an alkyl group having 1 to 3 carbon atoms, and m is preferably 1.

The above example is a specific example in a case where R¹ is a hydrogen atom, and R¹ is preferably any other than a hydrogen atom. The poly benzimidazole structure in this case is represented by formula (1′).

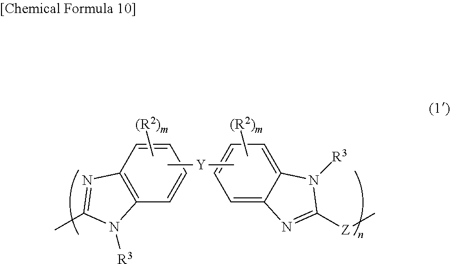

In formula (1′), R³ is each independently a substituent T selected from the group consisting an alkyl group having 1 to 30 carbon atoms and optionally having a substituent, an aryl group having 6 to 40 carbon atoms and optionally having a substituent, an aralkyl group having 7 to 40 carbon atoms and optionally having a substituent, an alkenyl group having 2 to 30 carbon atoms and optionally having a substituent, an alkynyl group having 2 to 30 carbon atoms and optionally having a substituent, an arylalkenyl group having 7 to 40 carbon atoms and optionally having a substituent, an alkoxy group having 1 to 30 carbon atoms and optionally having a substituent, a halogen atom, a nitro group, an amino group, a cyano group, a carboxylic acid group, a thiol group and a hydroxy group, wherein the aryl group, the aralkyl group, the alkenyl group, the alkynyl group and the arylalkenyl group each optionally include an ether bond, a ketone bond, an ester bond or a urethane bond. R², Y, Z, m, and n are as defined above.

R³ is any other than a hydrogen atom, and thus the resin is characterized by being excellent in solubility in a solvent and low in water absorbability due to the effects of inhibiting a hydrogen atom from forming a hydrogen bond and of causing intermolecular packing. Accordingly, a film for lithography formed from the resin is also excellent in heat resistance and etching resistance. R³ may be a crosslinking group. That is, a crosslinked structure may be formed by a reaction of R³(s) present in different repeating units, or a crosslinked structure may be formed between the resin and a crosslinking agent described below, by a reaction of R³ with the crosslinking agent. Specific examples of the crosslinking group include respective groups containing an alkenyl group, an alkynyl group, and an epoxy group. The resin having the structure represented by formula (1′) is useful for not only an application of a film for lithography, but also an injection-molding application, an extrusion application, and the like.

Polybenzimidazole can be obtained by a reaction of a tetraamino compound with a dicarboxylic acid, or a corresponding dicarboxylic acid chloride, or the like. Polybenzimidazole can be generally obtained by subjecting polyaminoamide as one polybenzimidazole precursor obtained by a reaction of a tetraamino compound with a dicarboxylic acid, to cyclodehydration due to heating or a chemical treatment with phosphoric anhydride, a base, a carbodiimide compound, or the like.

The tetraamino compound can encompass, for example, 3,3′,4,4-tetraaminobiphenyl, 2,3,5,6-tetraaminopyridine, 1,2,4,5-tetraaminobenzene, 3,3′,4,4′-tetraaminodiphenylsulfone, 3,3′,4,4′-tetraaminodiphenyl ether, 3,3′,4,4′-tetraaminobenzophenone, 3,3′,4,4′-tetraaminodiphenylmethane, and 3,3′,4,4′-tetraaminodiphenyldimethylmethane. Specific examples of the tetraamino compound which can be preferably used are shown below.

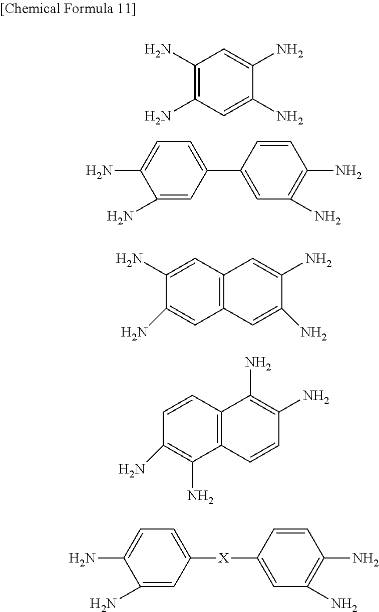

In the formula, X is represented by —O—, —S—, —CH₂—, —C(CH₃)₂—, —CO—, —SO₂—, —C(CF₃)₂—, —CONH—, or —COO—. In the present embodiment, tetraaminobiphenyl (TAB) is particularly preferable.

Examples of the dicarboxylic acid and the dicarboxylic acid chloride include dicarboxylic acids such as terephthalic acid, isophthalic acid, diphenyl etherdicarboxylic acid, bis(carboxyphenyl)hexafluoropropane, biphenyldicarboxylic acid, benzophenonedicarboxylic acid, and triphenyldicarboxylic acid; and acid chloride compounds obtained by acid chlorination of carboxyl groups in dicarboxylic acids such as terephthalic acid, phthalic acid, maleic acid, cyclohexanedicarboxylic acid, 3-hydroxyphthalic acid, 5-norbornene-2,3-dicarboxylic acid, 1,2-dicarboxynaphthalene, 1,3-dicarboxynaphthalene, 1,4-dicarboxynaphthalene, 1,5-dicarboxynaphthalene, 1,6-dicarboxynaphthalene, 1,7-dicarboxynaphthalene, 1,8-dicarboxynaphthalene, 2,3-dicarboxynaphthalene, 2,6-dicarboxynaphthalene, and 2,7-dicarboxynaphthalene.

The resin including the structure of formula (W′) can be obtained by allowing a resin having a structure of formula (1) where R¹ is a hydrogen atom to react with THal (T is as defined above and Hal is a halogen atom) as a halogen compound, in the presence of a base, to thereby substitute the hydrogen atom with T. The base here used can be, for example, sodium hydride. The reaction is preferably carried out in a solvent, and can be carried out at a temperature of about −20° C. to 120° C. by use of, for example, any amide such as N,N-dimethylacetamide (DMAc) or N-methyl-2-pyrrolidone; or any cyclic amino acetal such as dimethylimidazolidine or dimethylimidazolidinone (dimethylimidazolidine-dione). Here, cesium carbonate or the like can also be used.

The film forming material for lithography of the present embodiment can be applied to a wet process. The film forming material for lithography of the present embodiment has an aromatic structure and furthermore has a rigid benzimidazole backbone, and thus exhibits high heat resistance. Thus, the temperature in baking can be a high temperature, and not only film degradation can be suppressed, but also the concentration of carbon in a film can be increased. As a result, a film excellent in etching resistance against oxygen plasma etching or the like can be formed. Furthermore, the film forming material for lithography of the present embodiment, although has an aromatic structure, is high in solubility in an organic solvent and high in solubility in a safe solvent. Furthermore, an underlayer film for lithography, formed from a composition for film formation for lithography of the present embodiment, described below, not only is excellent in embedding properties to a substrate having difference in level and film flatness and favorable in stability of a production quality, but also is excellent in adhesion with a resist layer and a resist intermediate layer film material, and thus an excellent resist pattern can be obtained.

[Composition for Film Formation for Lithography]

A composition for film formation for lithography of the present embodiment contains the film forming material for lithography, and a solvent. The film for lithography is, for example, an underlayer film for lithography. The underlayer film for lithography is a layer present between a substrate and a photoresist layer.

<Solvent>

The solvent for use in the composition for film formation for lithography of the present embodiment is not particularly limited as long as it is dissolved in the resin having a polybenzimidazole structure, among components of the composition, and a known solvent can be appropriately used.

Specific examples of the solvent include any solvent described in International Publication No. WO 2013/024779. Such a solvent can be used singly or in combinations of two or more kinds thereof.

The solvent is particularly preferably an aprotic polar solvent such as dimethylsulfoxide, dimethylformamide, cyclohexanone, or anisole; a polyhydric alcohol ether such as propylene glycol monomethyl ether; or an ester such as propylene glycol monomethyl ether acetate, ethyl lactate, or methyl hydroxyisobutyrate, from the viewpoint of safety.

The content of the solvent is not particularly limited, and is preferably 25 to 9,900 parts by mass, more preferably 400 to 7,900 parts by mass, further preferably 900 to 4,900 parts by mass based on 100 parts by mass of the resin having a polybenzimidazole structure in the material for film formation for lithography, from the viewpoints of solubility and film formation.

<Acid Generating Agent>

The composition for film formation for lithography of the present embodiment may contain, if necessary, an acid generating agent from the viewpoint of further promotion of a crosslinking reaction. Acid generating agents known are, for example, one which generates an acid by pyrolysis and one which generates an acid by light irradiation, and both can be each used. At least one acid generating agent which directly or indirectly generates an acid by irradiation with any radiation selected from visible light, ultraviolet light, excimer laser, electron beam, extreme ultraviolet light (EUV), X-ray and ion beam is preferably included. For example, any acid generating agent described in International Publication No. WO 2013/024778 can be used. Such an acid generating agent can be used singly or in combinations of two or more kinds thereof.

The content of the acid generating agent in the composition for film formation for lithography of the present embodiment is not particularly limited, and is preferably 0 to 50 parts by mass, more preferably 0 to 40 parts by mass based on 100 parts by mass of the resin having a polybenzimidazole structure in the film forming material for lithography. The content is within the above preferable range to result in a tendency to enhance a crosslinking reaction and a tendency to suppress the occurrence of a mixing phenomenon with a resist layer.

<Basic Compound>

The composition for film formation for lithography of the present embodiment may further contain a basic compound from the viewpoint of, for example, an enhancement in storage stability.

The basic compound serves as a quencher of an acid, which prevents an acid generated in a trace amount from the acid generating agent from progressing a crosslinking reaction. Examples of the basic compound include, but not limited to the following, any primary, secondary or tertiary aliphatic amine, any mixed amine, any aromatic amine, any heterocyclic amine, any nitrogen-containing compound having a carboxy group, any nitrogen-containing compound having a sulfonyl group, any nitrogen-containing compound having a hydroxy group, any nitrogen-containing compound having a hydroxyphenyl group, any alcoholic nitrogen-containing compound, any amide derivative, or any imide derivative, described in International Publication No. WO 2013-024779.

The content of the basic compound in the composition for film formation for lithography of the present embodiment is not particularly limited, and is preferably 0 to 2 parts by mass, more preferably 0 to 1 part by mass based on 100 parts by mass of the resin having a polybenzimidazole structure in the film forming material for lithography. The content is within the above preferable range to result in a tendency to enhance storage stability without excessive loss of any crosslinking reaction.

The composition for film formation for lithography of the present embodiment may further contain a known additive. Examples of such a known additive include, but not limited to the following, an ultraviolet absorbent, a defoamer, a colorant, a pigment, a nonionic surfactant, an anionic surfactant, and a cationic surfactant.

<Crosslinking Agent>

The composition for film formation for lithography of the present embodiment may contain, if necessary, a crosslinking agent from the viewpoint of, for example, suppression of intermixing. The crosslinking agent usable in the present embodiment is not particularly limited, and, for example, any crosslinking agent described in International Publication No. WO 2013/024779 or International Publication No. WO 2018/016614 can be used. In the present embodiment, such a crosslinking agent can be used singly or in combinations of two or more kinds thereof.

Specific examples of the crosslinking agent usable in the present embodiment include a phenolic compound, an epoxy compound, a cyanate compound, an amino compound, a benzoxazine compound, an acrylate compound, a melamine compound, a guanamine compound, a glycoluril compound, a urea compound, an isocyanate compound, and an azide compound, but not particularly limited thereto. Such a crosslinking agent can be used singly or in combinations of two or more kinds thereof. In particular, a benzoxazine compound, an epoxy compound or a cyanate compound is preferable, and a benzoxazine compound is more preferable from the viewpoint of an enhancement in etching resistance.

The phenolic compound here used can be any known one and is not particularly limited, and an aralkyl-type phenolic resin is preferable from the viewpoints of heat resistance and solubility.

The epoxy compound here used can be any known one and is not particularly limited, and an epoxy resin which is in the form of a solid at ordinary temperature, obtained from a phenolaralkyl resin, a biphenylaralkyl resin, or the like, is preferable from the viewpoints of heat resistance and solubility.

The cyanate compound is not particularly limited as long as it is a compound having two or more cyanate groups in one molecule, and any known one can be used. In the present embodiment, examples of a preferable cyanate compound include one having a structure where a hydroxy group of a compound having two or more hydroxy groups in one molecule is substituted with a cyanate group. Such a cyanate compound preferably has an aromatic group, and such a compound having a structure where a cyanate group is directly bound to an aromatic group can be suitably used. Such a cyanate compound is not particularly limited, and examples thereof include those each having a structure where a hydroxy group of a compound is substituted with a cyanate group. Examples of the compound include bisphenol A, bisphenol F, bisphenol M, bisphenol P, bisphenol E, a phenol novolak resin, a cresol novolak resin, a dicyclopentadiene novolak resin, tetramethyl bisphenol F, a bisphenol A novolak resin, brominated bisphenol A, a brominated phenol novolak resin, trifunctional phenol, tetrafunctional phenol, naphthalene-type phenol, biphenyl-type phenol, a phenol aralkyl resin, a biphenyl aralkyl resin, a naphthol aralkyl resin, a dicyclopentadiene aralkyl resin, alicyclic phenol, and phosphorus-containing phenol. Such a cyanate compound may be in any form of a monomer, an oligomer, and a resin.

The amino compound here used can be any known one and is not particularly limited, and 4,4′-diaminodiphenylmethane, 4,4′-diaminodiphenylpropane, and 4,4′-diaminodiphenyl ether are preferable from the viewpoints of heat resistance and availability of a raw material.

The benzoxazine compound here used can be any known one and is not particularly limited, and is preferably P-d type benzoxazine obtained from a bifunctional amine compound and a monofunctional phenol compound, from the viewpoint of heat resistance.

The melamine compound here used can be any known one and is not particularly limited, and is preferably hexamethylolmelamine, hexamethoxymethylmelamine, a compound obtained by methoxymethylation of 1 to 6 methylol groups of hexamethylolmelamine, or a mixture thereof, from the viewpoint of availability of a raw material.

The guanamine compound here used can be any known one and is not particularly limited, and is preferably a compound obtained by methoxymethylation of 1 to 4 methylol groups of tetramethylolguanamine such as tetramethylolguanamine, tetramethoxymethylguanamine, or a mixture thereof, from the viewpoint of heat resistance.

The glycoluril compound here used can be any known one and is not particularly limited, and is preferably tetramethylolglycoluril or tetramethoxyglycoluril from the viewpoints of heat resistance and etching resistance.

The urea compound here used can be any known one and is not particularly limited, and is preferably tetramethylurea or tetramethoxymethylurea from the viewpoint of heat resistance.

In the present embodiment, a crosslinking agent having at least one allyl group may be used from the viewpoint of an enhancement in crosslinkability. In particular, allylphenols such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl)sulfide, and bis(3-allyl-4-hydroxyphenyl)ether are preferable.

The film forming material for lithography of the present embodiment can be used to form a film for lithography of the present embodiment by compounding the resin having a polybenzimidazole structure singly or together with the crosslinking agent, and subjecting the resultant to crosslinking and curing by a known method. Examples of the crosslinking method include procedures such as thermal cuing and photo-curing.

The content ratio of the crosslinking agent is, for example, in the range from 0.1 to 100 parts by mass, and is preferably in the range from 1 to 50 parts by mass, more preferably in the range from 1 to 30 parts by mass based on 100 parts by mass of the resin having a polybenzimidazole structure, from the viewpoints of heat resistance and solubility.

<Crosslinking Promoting Agent>

A crosslinking promoting agent for prompting crosslinking and curing reactions can be, if necessary, used in the composition for film formation for lithography of the present embodiment.

The crosslinking promoting agent is not particularly limited as long as it promotes crosslinking and curing reactions, and examples thereof include amines, imidazoles, organic phosphines, and Lewis acid. Such a crosslinking promoting agent can be used singly or in combinations of two or more kinds thereof. In particular, imidazoles or organic phosphines are preferable, and imidazoles are more preferable from the viewpoint of a decrease in crosslinking temperature.

The crosslinking promoting agent here used can be any known one and is not particularly limited, and examples include any crosslinking promoting agent described in International Publication No. WO 2018/016614. In particular, 2-methylimidazole, 2-phenylimidazole, and 2-ethyl-4-methylimidazole are preferable from the viewpoints of heat resistance and promotion of curing.

The content of the crosslinking promoting agent based on 100 parts by mass of the total mass of the resin having a polybenzimidazole structure and the crosslinking agent is usually preferably 0.1 to 10 parts by mass, and is more preferably 0.1 to 5 parts by mass, further preferably 0.1 to 3 parts by mass from the viewpoints of ease of control and economic efficiency.

<Radical Polymerization Initiator>

A radical polymerization initiator can be, if necessary, compounded into the composition for film formation for lithography of the present embodiment. The radical polymerization initiator may be a photopolymerization initiator which initiates radical polymerization by light, or may be a thermal polymerization initiator which initiates radical polymerization by heat. The radical polymerization initiator can be, for example, at least one selected from a ketone-based photopolymerization initiator, an organic peroxide-based polymerization initiator, and an azo-based polymerization initiator.

The radical polymerization initiator is not particularly limited, and one conventionally used can be appropriately adopted. Examples include any radical polymerization initiator described in International Publication No. WO 2018/016614. In particular, dicumyl peroxide, 2,5-dimethyl-2,5-bis(t-butylperoxy)hexane, and t-butyl cumyl peroxide are particularly preferable from the viewpoints of availability and storage stability of a raw material.

Such an initiator can be used singly, in combinations of two or more kinds thereof, or in further combinations thereof with other known polymerization initiator, as the radical polymerization initiator for use in the present embodiment.

The content of the radical polymerization initiator may be any stoichiometrically necessary amount relative to the mass of the resin having a polybenzimidazole structure, and is preferably 0.05 to 25 parts by mass, more preferably 0.1 to 10 parts by mass based on 100 parts by mass of the resin having a polybenzimidazole structure. In a case where the content of the radical polymerization initiator is 0.05 parts by mass or more, insufficient curing of polybenzimidazole tends to be able to be prevented, and on the other hand, in a case where the content of the radical polymerization initiator is 25 parts by mass or less, the film forming material for lithography tends to be able to be prevented from being lost in long-term storage stability at room temperature.

<Film Formation>

A desired cured film can be formed by coating a base material with the composition for film formation for lithography of the present embodiment, thereafter, if necessary, heating the resultant to evaporate the solvent, and thereafter subjecting the resultant to heating or light irradiation. The method for coating with the composition for film formation for lithography of the present embodiment is any method, and, for example, a method such as a spin coating method, a dipping method, a flow coating method, an inkjet method, a spraying method, a bar coating method, a gravure coating method, a slit coating method, a roll coating method, a transfer printing method, brush coating, a blade coating method, or an air knife coating method can be appropriately adopted.

The heating temperature of the film is not particularly limited in terms of evaporation of the solvent, and can be, for example, 40 to 400° C. The heating method is not particularly limited, and may be performed by, for example, evaporation using a hot plate or an oven in an appropriate atmosphere of air, an inert gas such as nitrogen or vacuum. The heating temperature and the heating time may be selected so as to be adapted to a process step of an objective electronic device, and the heating condition(s) may be selected so that physical property value(s) of the resulting film is/are adapted to requirement properties of such an electronic device. The condition(s) in the case of light irradiation is/are also not particularly limited, and appropriate irradiation energy and irradiation time may be adopted depending on the film forming material for lithography, to be used.

The C/O ratio in the film for lithography can be controlled to result in an enhancement in etching resistance, and thus the film may be baked so as to achieve a preferable C/O ratio. For example, a high ratio leads to high resistance against oxygen plasma etching or etching by a fluorine-based gas. The baking temperature is not particularly limited, is usually in the range from 200° C. to 1000° C., and is preferably 300 to 900° C., more preferably 400° C. to 800° C., further preferably 450° C. to 700° C., still further preferably 500° C. to 700° C. from the viewpoints of high carbonization and heat resistance of the film. The baking time is also not particularly limited, and is preferably in the range from 10 to 300 seconds.

[Underlayer Film for Lithography and Method for Forming Pattern]

An underlayer film for lithography of the present embodiment is formed using the composition for film formation for lithography of the present embodiment.

A method for forming a pattern of the present embodiment includes step (A-1) of forming an underlayer film on a substrate using he composition for film formation for lithography of the present embodiment, step (A-2) of forming at least one photoresist layer on the underlayer film, and step (A-3) of irradiating a predetermined region of the photoresist layer with radiation for development, after step (A-2).

Another method for forming a pattern of the present embodiment includes step (B-1) of forming an underlayer film on a substrate using the composition for film formation for lithography of the present embodiment; step (B-2) of forming an intermediate layer film on the underlayer film using a silicon atom-containing resist intermediate layer film material; step (B-3) of forming at least one photoresist layer on the intermediate layer film; step (B-4) of irradiating a predetermined region of the photoresist layer with radiation for development to thereby form a resist pattern, after step (B-3); and step (B-5) of etching the intermediate layer film with the resist pattern as a mask, etching the underlayer film with an intermediate layer film pattern obtained, as an etching mask, and etching the substrate with an underlayer film pattern obtained, as an etching mask, to thereby form a pattern on the substrate, after step (B-4).

The method for forming the underlayer film for lithography of the present embodiment (hereinafter, also simply referred to as “underlayer film”) is not particularly limited as long as the underlayer film is formed from the composition for film formation for lithography of the present embodiment, and a known procedure can be applied. For example, the underlayer film can be formed by applying the composition for film formation for lithography of the present embodiment to a substrate by a known coating method or printing method such as spin coating or screen printing, and thereafter removing an organic solvent by volatilization or the like.

When the underlayer film is formed, baking is preferably performed in order to not only suppress the occurrence of a mixing phenomenon with an upper layer resist, but also promote a crosslinking reaction, or achieve a preferable C/O ratio. The baking conditions are as described above. The thickness of the underlayer film can be appropriately selected depending on requirement performance, is not particularly limited, and is usually preferably 30 to 20.000 nm, more preferably 50 to 15,000 nm, further preferably 50 to 1000 nm.

After the underlayer film is produced on the substrate, preferably a silicon-containing resist layer or a usual single-layer resist including hydrocarbon is produced thereon in the case of a two-layer process, and preferably a silicon-containing intermediate layer is produced thereon and a silicon-free single-layer resist layer is further produced thereon in the case of a three-layer process. In this case, a known material can be used as a photoresist material for formation of the resist layer.

The silicon-containing resist material for use in a two-layer process is preferably a positive photoresist material including a silicon atom-containing polymer as a base polymer, such as a polysilsesquioxane derivative or a vinylsilane derivative, and further including, for example, an organic solvent, an acid generating agent, and, if necessary, a basic compound, from the viewpoint of oxygen gas etching resistance. The silicon atom-containing polymer here used can be a known polymer used in such a resist material.

The silicon-containing intermediate layer for use in a three-layer process is preferably a polysilsesquioxane-based intermediate layer. The intermediate layer is allowed to have a function as an antireflective film, resulting in a tendency to enable reflection to be effectively suppressed. For example, if a material including many aromatic groups and having high substrate etching resistance is used in the underlayer film in a process for 193-nm exposure, a high k value and high substrate reflection tend to be caused, but the intermediate layer can suppress reflection to thereby allow substrate reflection to be 0.5% or less. Such an intermediate layer having an antireflective effect, here used for 193-nm exposure, preferably includes, but not limited to the following, polysilsesquioxane into which a phenyl group or an light absorption group having a silicon-silicon bond is introduced. Such polysilsesquioxane is to be crosslinked by an acid or heat.

An intermediate layer formed by a Chemical Vapour Deposition (CVD) method can also be used. For example, a SiON film is known as an intermediate layer highly effective as an antireflective film produced by a CVD method, but not limited thereto. In general, formation of an intermediate layer by a wet process such as a spin coating method or screen printing is simple and has an advantage in cost as compared with by a CVD method. An upper layer resist in a three-layer process may be positive or negative, and the same resist as the single-layer resist usually used can be used.

An underlayer film of the present embodiment can also be used as an antireflective film for a usual single-layer resist or as an underlying material for suppression of pattern collapse. The underlayer film of the present embodiment is excellent in etching resistance for underlying processing, and thus can also be expected to function as a hard mask for underlying processing.

In a case where a resist layer is formed by the photoresist material, a wet process such as a spin coating method or screen printing is preferably used as in the case of formation of the underlayer film. After coating with the resist material according to a spin coating method or the like, pre-baking is usually performed, and the pre-baking is preferably performed at 80 to 180° C. for 10 to 30) seconds. Thereafter, exposure can be performed and post-exposure baking (PEB) and development can be performed according to ordinary methods, to thereby provide a resist pattern. The thickness of a resist film is not particularly limited, and is generally preferably 30 to 500 nm, more preferably 50 to 400 nm.

The exposure light may be appropriately selected and used depending on the photoresist material used. Examples can commonly include high energy line having a wavelength of 300 nm or less, specifically, excimer lasers at 248 nm, 193 nm and 157 nm, soft X-ray at 3 to 20 nm, electron beam, and X-ray.

A resist pattern formed by the above method is suppressed in pattern collapse by the underlayer film of the present embodiment. Therefore, the underlayer film of the present embodiment can be used to thereby obtain a finer pattern and also reduce the amount of exposure necessary for obtaining such a resist pattern.

Next, the resulting resist pattern is used as a mask to perform etching. Gas etching is preferably used as etching of the underlayer film in a two-layer process. Gas etching is suitably etching using an oxygen gas. Not only an oxygen gas, but also an inert gas such as He or Ar, or CO, CO₂, NH₃, SO₂, N₂, NO₂, or H₂ gas(es) can also be added. Gas etching can also be performed without use of any oxygen gas by using only CO, CO₂, NH₃, N₂, NO₂, or H₂ gas(es). In particular, the latter gas(es) is/are preferably used for side wall protection for prevention of undercutting of a pattern side wall.

Gas etching is preferably used also as etching of the intermediate layer in a three-layer process. Gas etching here applied can be the same as that described above with respect to a two-layer process. In particular, processing of the intermediate layer in a three-layer process is preferably performed using a fluorocarbon gas with a resist pattern as a mask. Thereafter, for example, oxygen gas etching can be performed with an intermediate layer pattern as a mask, as described above, thereby performing processing of the underlayer film.

In a case where an intermediate layer film as an inorganic hard mask is formed as the intermediate layer, a silicon oxide film, a silicon nitride film, or a silicon oxide nitride film (SiON film) is formed by a CVD method, an ALD method, or the like. The method for forming a nitride film is, but not limited to the following, for example, any method described in Japanese Patent Laid-Open No. 2002-334869 (PTL 6) or WO 2004/066377 (PTL 7). While a photoresist film can be formed directly on such an intermediate layer film, a photoresist film may be formed on an organic antireflective film (BARC) formed on such an intermediate layer film by spin coating.

A polysilsesquioxane-based intermediate layer is also preferably used as the intermediate layer. A resist intermediate layer film can be allowed to have the effect as an antireflective film, to result in a tendency to effectively suppress reflection. A specific material of the polysilsesquioxane-based intermediate layer, here used, can be, but not limited to the following, any material described in Japanese Patent Laid-Open No. 2007-226170 (PTL 8) or Japanese Patent Laid-Open No. 2007-226204 (PTL 9).

The next etching of the substrate can also be performed by an ordinary method, and, for example, etching mainly with a chlorofluorocarbon gas can be performed in a case where the substrate is made of SiO₂ or SiN, and etching mainly with a chlorine-based or bromine-based gas can be performed in a case where the substrate is made of p-Si, Al, or W. In a case where the substrate is etched with a chlorofluorocarbon gas, the silicon-containing resist in a two-layer resist process and the silicon-containing intermediate layer in a three-layer process can be peeled at the same time as processing of the substrate. On the other hand, in a case where the substrate is etched with a chlorine-based or bromine-based gas, the silicon-containing resist layer or the silicon-containing intermediate layer is separately peeled, in general, peeled by dry etching with a chlorofluorocarbon gas after processing of the substrate.

The underlayer film of the present embodiment is characterized by being excellent in etching resistance of the substrate. The substrate can be appropriately selected from known substrates and used, and is not particularly limited, and examples thereof include Si, α-Si, p-Si, SiO₂, SiN, SiON, W, TiN, and Al. The substrate may be a laminate having on a base material (support) a film to be processed (substrate to be processed). Examples of the film to be processed include various Low-k films of Si, SiO₂, SiON, SiN, p-Si, α-Si, W, α-Si, Al, Cu, Al—Si, and the like, and stopper films thereof, and any substrate whose material is different from the base material (support) is usually used. The thickness of the substrate of interest or the film to be processed is not particularly limited, and is usually preferably about 50 to 1,000,000 nm, more preferably 75 to 500,000 nm.

[Resist Permanent Film]

A resist permanent film is produced by the composition for film formation for lithography of the present embodiment. The resist permanent film produce by coating a base material or the like with the composition is suitable as a permanent film which remains also in a final product, if necessary, after formation of a resist pattern. A specific example of the permanent film is not particularly limited, and examples include a solder resist, a packaging material, an underfill material, a packaging adhesion layer for a circuit element or the like, and an adhesion layer for an integrated circuit element or a circuit substrate, in a semiconductor device, as well as a protective film of a thin-film transistor, a protective film of a liquid crystal color filter, a black matrix, and a spacer, in a thin display. In particular, the permanent film also has very excellent advantages of being excellent in heat resistance and moisture resistance and of causing less contamination ability due to a sublimation component. In particular, the permanent film serves as a material causing less image degradation due to heavy contamination and simultaneously satisfying high sensitivity, high heat resistance, and moisture absorption reliability, in a display material.

In a case where the composition is used in a resist permanent film application, the composition can be obtained as a composition for the resist permanent film by adding not only a curing agent, but also, if necessary, other resin, and various additives such as a surfactant, a dye, a filler, a crosslinking agent, or a dissolution promoting agent, and dissolving the resultant in an organic solvent.

The composition for the resist permanent film can be prepared by compounding the above respective components, and mixing the resultant by use of a stirrer or the like. In a case where a filler or a pigment is/are used, the composition for the resist permanent film can be prepared by dispersing or mixing by use of a dispersing apparatus such as a dissolver, a homogenizer, or a triple roll mill.

[Purification Method of Film Forming Material for Lithography]

The film forming material for lithography can be washed and purified with an acidic aqueous solution. The purification method includes a step of dissolving the film forming material for lithography in an organic solvent that does not mix with water at any ratio to obtain an organic phase, contacting the organic phase with an acidic aqueous solution to thereby perform an extraction treatment (first extraction step), thereby transferring a metal component included in the organic phase including the film forming material for lithography and the organic solvent, to an aqueous phase, and then separating the organic phase and the aqueous phase. The purification can remarkably reduce the content of various metals in the film forming material for lithography of the present invention.

The organic solvent that does not mix with water at any ratio is usually an organic solvent classified into a water-insoluble solvent. The organic solvent is not particularly limited, and is preferably an organic solvent that can be safely applied to a process for producing a semiconductor. The amount of the organic solvent used is usually 1 to 100 times by mass that of the compound used.

Specific examples of the organic solvent used include any solvent described in International Publication No. WO 2015/080240. In particular, toluene, 2-heptanone, cyclohexanone, cyclopentanone, methyl isobutyl ketone, propylene glycol monomethyl ether acetate, ethyl acetate, and the like are preferable, and cyclohexanone and propylene glycol monomethyl ether acetate are preferable. Such organic solvents can be each used singly or as a mixture of two or more kinds thereof.

The acidic aqueous solution is appropriately selected from an aqueous solution commonly known, where an organic or inorganic compound is dissolved in water. Examples include any acidic aqueous solution described in International Publication No. WO 2015/080240. Such acidic aqueous solutions can be each used singly or in combinations of two or more kinds thereof. Examples of the acidic aqueous solution can include an aqueous mineral acid solution and an aqueous organic acid solution. Examples of the aqueous mineral acid solution can include an aqueous solution including at least one selected from the group consisting of hydrochloric acid, sulfuric acid, nitric acid, and phosphoric acid. Examples of the aqueous organic acid solution can include an aqueous solution including at least one selected from the group consisting of acetic acid, propionic acid, oxalic acid, malonic acid, succinic acid, fumaric acid, maleic acid, tartaric acid, citric acid, methanesulfonic acid, phenolsulfonic acid, p-toluenesulfonic acid, and trifluoroacetic acid. The acidic aqueous solution is preferably an aqueous solution of any of sulfuric acid, nitric acid, and acetic acid, or an aqueous solution of carboxylic acid such as oxalic acid, tartaric acid, or citric acid, further preferably an aqueous solution of sulfuric acid, oxalic acid, tartaric acid, or citric acid, particularly preferably an aqueous solution of oxalic acid. It is considered that a polyvalent carboxylic acid such as oxalic acid, tartaric acid, or citric acid can be coordinated to a metal ion to exert a chelating effect, thereby more removing a metal. The water here used is preferably one low in metal content according to an object of the present invention, for example, ion-exchange water.

The pH of the acidic aqueous solution is not particularly limited, and a too high acidity of the aqueous solution is not preferable because of sometimes having an adverse effect on the compound or resin used. The range of the pH is usually from about 0 to 5, more preferably about 0 to 3.

The amount of the acidic aqueous solution used is not particularly limited, and a too small amount thereof causes a need for an increase in number of times of extraction for metal removal, and on the contrary, a too large amount thereof leads to an increase in amount of the entire liquid to thereby sometimes cause any problem about an operation. The amount of the aqueous solution used is usually 10 to 200 parts by mass, preferably 20 to 100 parts by mass, based on that of the solution for the film forming material for lithography.

The acidic aqueous solution can be contacted with a solution including the film forming material for lithography and the organic solvent that does not mix with water at any ratio to thereby allow a metal component to be extracted.

The temperature in the extraction treatment is usually in the range from 20 to 90° C., preferably 30 to 80° C. Such an extraction operation is performed by, for example, well mixing with stirring or the like and thereafter still standing. Thus, the metal component included in the solution including the compound used and the organic solvent is transferred to the aqueous phase. The operation can also inhibit the compound used from being altered due to a reduction in acidity of the solution.

After the extraction treatment, separation between the organic phase including the compound used and the organic solvent and the aqueous phase is made, and the organic phase is recovered by decantation or the like. The still standing time is not particularly limited, and a too short still standing time is not preferable because of causing deterioration in separation between the organic phase and the aqueous phase. The still standing time is usually 1 minute or more, more preferably 10 minutes or more, further preferably 30 minutes or more. The extraction treatment may be performed only once and it is also effective to repeatedly perform an operation including mixing, still standing and separation multiple times.

In a case where the extraction treatment is performed using the acidic aqueous solution, it is preferable to perform extraction from the aqueous solution after the treatment and subject an organic phase including the organic solvent recovered, to an additional extraction treatment (second extraction step) with water. Such an extraction operation is performed by well mixing with stirring or the like and thereafter still standing. A solution obtained is separated to an organic phase and an aqueous phase and thus the organic phase is recovered by decantation or the like. The water here used is preferably one low in metal content according to an object of the present invention, for example, ion-exchange water. The extraction treatment may be performed only once and it is also effective to repeatedly perform an operation including mixing, still standing and separation multiple times. The conditions of the extraction treatment, for example, the ratio between both the treatment only once and the treatment of multiple operations used, the temperature, and the time are not particularly limited, and may be the same as those in the case of the above treatment by contacting with the acidic aqueous solution.

While moisture is incorporated in the organic phase including the film forming material for lithography and the organic solvent, thus obtained, the moisture can be easily removed by an operation such as distillation under reduced pressure. The concentration of the compound can be adjusted to any concentration by, if necessary, adding the organic solvent.

Only the film forming material for lithography can be obtained from the organic phase by use of a known method such as removal under reduced pressure, separation by re-precipitation, and a combination thereof. A known treatment such as a concentration operation, a filtration operation, a centrifugation operation, or a drying operation can be, if necessary, performed.

### EXAMPLES

Hereinafter, the present invention is still more specifically described with reference to Examples, Production Example, and Comparative Examples, but the present invention is not limited to such Examples at all.

[Molecular Weight]

The molecular weight Mn and Mw/Mn of each resin synthesized were measured by determining the molecular weight in terms of polystyrene by gel permeation chromatographic (GPC) analysis in the following conditions.

Apparatus: Shodex GPC-101 Model (manufactured by Showa Denko K.K.)

Column: KF-80M×3

Eluent: DMF 1 mL/min

Temperature: 40° C.

[Evaluation of Heat Resistance]

The thermogravimetric weight loss was measured by using EXSTAR 6000 TG-DTA apparatus manufactured by SII Nano Technology Inc., loading about 5 mg of each resin having a polybenzimidazole structure, obtained in Synthesis Examples described below, into an unsealed container made of aluminum, and raising the temperature to 500° C. at a rate of temperature rise of 10° C./min in a nitrogen gas (100 ml/min) stream. The results are shown in Table 1. Rating A or B described below is preferable from a practical viewpoint. Rating A or B allows high heat resistance to be achieved and can allow for application to baking at a high temperature. The evaluation criteria are as follows.

A: a thermogravimetric weight loss at 400° C., of less than 10%

B: a thermogravimetric weight loss at 400° C., of 10% to 25%

C: a thermogravimetric weight loss at 400° C., of more than 25%

[Evaluation of solubility]

A 50-ml screw bottle was charged with dimethylsulfoxide (DMSO) and each resin having a polybenzimidazole structure, obtained in Synthesis Examples described below, the resultant was stirred with a magnetic stirrer at 23° C. for 1 hour, and thereafter the amount dissolved in the mixed solvent was measured and the results were evaluated according to the following criteria. The results are shown in Table 1. Rating A or B described below is preferable from a practical viewpoint. Rating A or B allows high storage stability in the form of a solution to be achieved and can allow for sufficient application to a semiconductor fine processing process.

A: 10 mass % or more

B: 5 mass % or more and less than 10 mass %

C: less than 5 mass %

### Synthesis Example 1

3,3′,4,4′-Tetraaminobiphenyl (manufactured by Kanto Chemical Co., Inc.; 3.14 g, 10 mmol) was added to polyphosphoric acid (50 g) in a 200-mL eggplant flask, and stirred in an oil bath at 160° C. for 3 hours to dissolve the tetraaminobiphenyl in the polyphosphoric acid. Isophthalic acid (manufactured by Mitsubishi Gas Chemical Company, Inc.; 1.46 g, 10 mmol) was added to a uniform solution, and the resultant was stirred for 24 hours after the temperature of the oil bath was raised to 200° C. Next, the reaction mixture was cooled to 80° C. (when possible, cooled to room temperature), and 100 mL of distilled water was carefully added thereto. The mixed liquid was stirred at room temperature for 1 hour and thereafter suction filtered, the residue was washed with distilled water (20 mL×5), thereafter 200 mL of an aqueous saturated sodium hydrogen carbonate solution was added thereto, and the resultant was stirred at room temperature for 6 hours. Furthermore, the residue was washed with distilled water (50 mL×10) and acetone (20 mL×10) with suction filtration, and the residue was dried in vacuum at 100° C. for 24 hours to thereby obtain polybenzimidazole represented by the following formula, as a beige solid at a yield of 98% (3.15 g). A resin obtained had a molecular weight Mn of 11800 and a polydispersity Mw/Mn of 2.9.

### Synthesis Example 1-1

Dry DMF (50 mL) was added to polybenzimidazole PBI-n (771 mg, 2.5 mmol) obtained in Synthesis Example 1, in a 100-mL eggplant flask, and thus a uniform solution was prepared. Cesium carbonate (2.44 g, 7.5 mmol) was added to the solution and stirred at room temperature for 30 minutes, and thereafter benzyl bromide (1.03 g, 6 mmol) was dropped thereinto over 10 minutes. The reaction mixture was stirred at room temperature for 12 hours and thereafter dropped into 200 mL of methanol to thereby obtain a fibrous precipitate. The precipitate was washed with methanol (50 mL×10) with suction filtration, and the residue was dried in vacuum at 60° C. for 24 hours to thereby obtain benzyl-protected polybenzimidazole represented by the following formula, as a beige solid at a yield of 97% (1.18 g). A resin obtained had a molecular weight Mn of 18690 and a polydispersity Mw/Mn of 2.8.

### Synthesis Example 1-2

Dry DMF (50 mL) was added to polybenzimidazole PBI-n (771 mg, 2.5 mmol) obtained in Synthesis Example 1, in a 100-mL eggplant flask, and thus a uniform solution was prepared. Cesium carbonate (2.44 g, 7.5 mmol) was added to the solution and stirred at room temperature, and thereafter ethanol bromide (0.32 g, 6 mmol) was dropped thereinto. The reaction mixture was stirred at room temperature for 6 hours and thereafter dropped into 200 mL of methanol to thereby obtain a fibrous precipitate. The precipitate was washed with methanol (50 mL×10) with suction filtration, and the residue was dried in vacuum at 60° C. for 24 hours to thereby obtain hydroxyethyl-protected poly benzimidazole represented by the following formula, at a yield of 95% (1.18 g). A resin obtained had a molecular weight Mn of 13200 and a polydispersity Mw/Mn of 2.9.

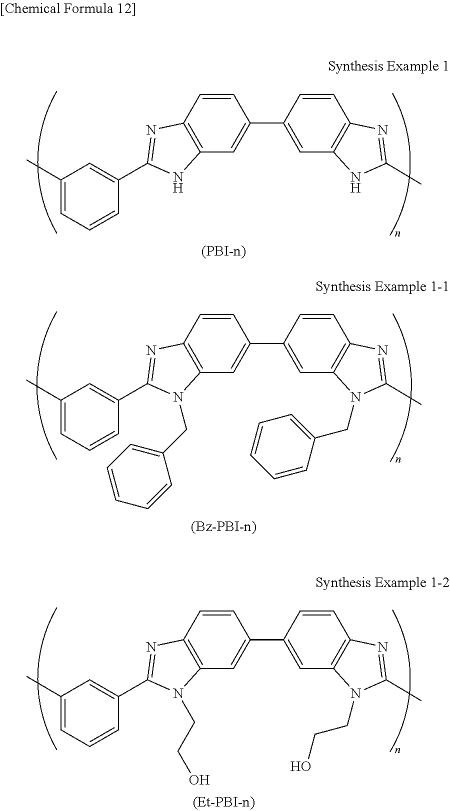

### Synthesis Example 2

Polybenzimidazole represented by the following formula was obtained at a yield of 97% (3.49 g) in the same conditions as those in Synthesis Example 1 except that the tetraaminobiphenyl of Synthesis Example 1 was changed to 3,3′,4,4′-tetraaminooxydiphenyl (manufactured by Kanto Chemical Co., Inc.). A resin obtained had a molecular weight Mn of 5800 and a polydispersity Mw/Mn of 2.2.

### Synthesis Example 2-1

Benzyl-protected polybenzimidazole (Bz-PBI-E) represented by the following formula was obtained at a yield of 96% in the same conditions as those in Synthesis Example 1-1 except that PBI-E obtained in Synthesis Example 2 was used instead of PBI-n obtained in Synthesis Example 1. A resin obtained had a molecular weight Mn of 9020 and a polydispersity Mw/Mn of 2.3.

### Synthesis Example 2-2

Hydroxyethyl-protected polybenzimidazole (Et-PBI-E) represented by the following formula was obtained at a yield of 94% in the same conditions as those in Synthesis Example 1-2 except that PBI-E obtained in Synthesis Example 2 was used instead of PBI-n obtained in Synthesis Example 1. A resin obtained had a molecular weight Mn of 7130 and a polydispersity Mw/Mn of 2.1.

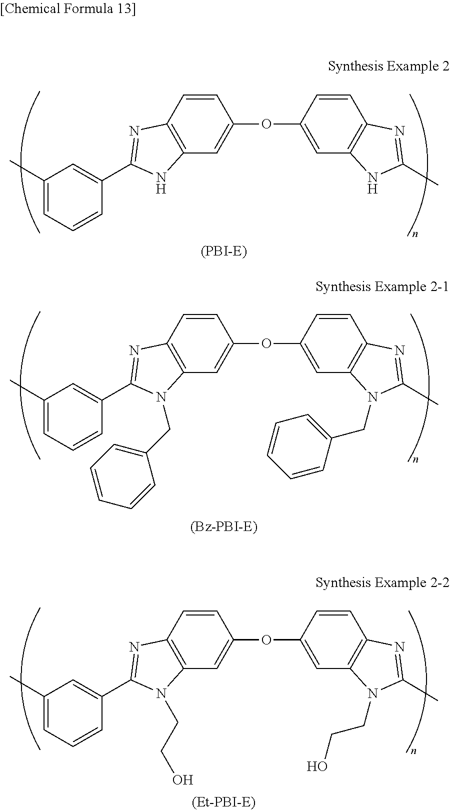

### Synthesis Example 3

Polybenzimidazole (PBI-S) represented by the following formula was obtained at a yield of 95% in the same conditions as those in Synthesis Example 1 except that the tetraaminobiphenyl of Synthesis Example 1 was changed to 3,3′,4,4′-tetraaminophenyl ether sulfone (manufactured by Kanto Chemical Co., Inc.). A resin obtained had a molecular weight Mn of 9300 and a polydispersity Mw/Mn of 6.9.

### Synthesis Example 3-1

Benzyl-protected poly benzimidazole (Bz-PBI-S) represented by the following formula was obtained at a yield of 95% in the same conditions as those in Synthesis Example 1-1 except that PBI-S obtained in Synthesis Example 3 was used instead of PBI-n obtained in Synthesis Example 1. A resin obtained had a molecular weight Mn of 13800 and a polydispersity Mw/Mn of 7.2.

### Synthesis Example 3-2

Hydroxyethyl-protected polybenzimidazole (Et-PBI-S) represented by the following formula was obtained at a yield of 94% in the same conditions as those in Synthesis Example 1-2 except that PBI-S obtained in Synthesis Example 3 was used instead of PBI-n obtained in Synthesis Example 1. A resin obtained had a molecular weight Mn of 11200 and a polydispersity Mw/Mn of 6.9.

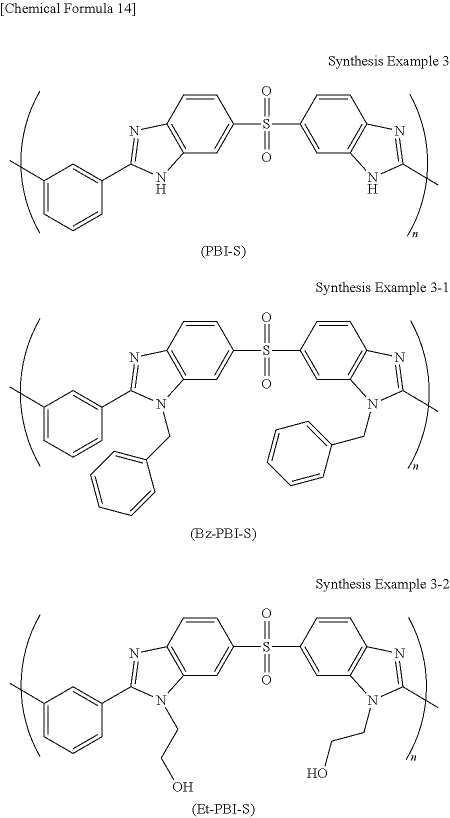

### Production Example 1

A four-necked flask was prepared which was equipped with a Dimroth condenser, a thermometer and a stirring blade, which had a detachable bottom, and which had an inner volume of 10 L. The four-necked flask was charged with 1.09 kg of 1,5-dimethylnaphthalene (7 mol, manufactured by Mitsubishi Gas Chemical Company, Inc.), 2.1 kg of an aqueous 40 mass % formalin solution (28 mol of formaldehyde, manufactured by Mitsubishi Gas Chemical Company, Inc.) and 0.97 ml of 98 mass % sulfuric acid (manufactured by Kanto Chemical Co., Inc.) in a nitrogen stream, and the resultant was allowed to react under reflux at 100° C. under ordinary pressure for 7 hours. Thereafter, 1.8 kg of ethylbenzene (manufactured by FUJIFILM Wako Pure Chemical Corporation, special grade reagent) as a dilution solvent was added to a reaction liquid, the resultant was left to still stand, and thereafter an aqueous phase as a bottom phase was removed. Furthermore, the resultant was neutralized and washed with water, and the ethylbenzene and the unreacted 1,5-dimethylnaphthalene were distilled off under reduced pressure, to thereby obtain 1.25 kg of a dimethylnaphthalene formaldehyde resin as a light brown solid. The molecular weight of the dimethylnaphthalene formaldehyde resin obtained was as follows: the number average molecular weight (Mn) was 562, the weight average molecular weight (Mw) was 1168, and the dispersity (Mw/Mn) was 2.08.

Subsequently, a four-necked flask was prepared which was equipped with a Dimroth condenser, a thermometer and a stirring blade and which had an inner volume of 0.5 L. Into the four-necked flask were 100 g (0.51 mol) of the dimethylnaphthalene formaldehyde resin obtained as above and 0.05 g of p-toluenesulfonic acid in a nitrogen stream, and subjected to a temperature rise to 190° C. and heated for 2 hours, and thereafter stirred. Thereafter, 52.0 g (0.36 mol) of 1-naphthol was added, and the resultant was further heated to 220° C. and allowed to react for 2 hours. After solvent dilution, the resultant was neutralized and washed with water, and the solvent was removed under reduced pressure, to thereby obtain 126.1 g of a modified resin (CR-1) as a blackish brown solid. The resin (CR-1) obtained had a Mn of 885, a Mw of 2220, and a Mw/Mn of 2.51.

TABLE 1

| | Benzimidazole resin | Solubility | Heat resistance |
|---|---|---|---|
| Synthesis Example 1 | PRI-n(10) | B | A |
| Synthesis Example 1-1 | Bz-PBI-n(10) | A | A |
| Synthesis Example 1-2 | Et-PBI-n(10) | A | A |
| Synthesis Example 2 | PBI-E(10) | B | A |
| Synthesis Example 2-1 | Bz-PBI-E(10) | A | A |
| Synthesis Example 2-2 | Et-PBI-E(10) | A | A |
| Synthesis Example 3 | PBI-S(10) | B | A |
| Synthesis Example 3-1 | Bz-PBT-S(10) | A | A |
| Synthesis Example 3-2 | Et-PM-S(10) | A | A |
| Production Example 1 | CR-1 | A | C |

### Examples 1 to 15 and Comparative Examples 1 to 2

The resin obtained in Synthesis Example and DMSO were used to prepare each composition for film formation for lithography, having a compositional profile as shown in Table 2 (Examples 1 to 15). The resin obtained in Production Example 1 was used to prepare each comparative composition for film formation for lithography (Comparative Examples 1 to 2). A phenylaralkyl-type epoxy resin (NC-3000-L: manufactured by Nippon Kayaku Co., Ltd.) as a crosslinking agent is represented by the following formula.

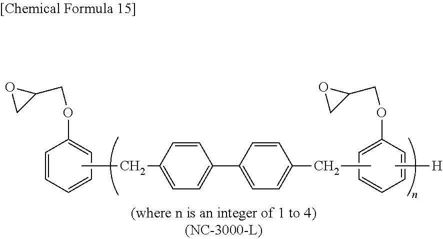

Next, a silicon substrate was rotated and coated with each of the compositions for film formation for lithography, of Examples 1 to 15 and Comparative Examples 1 to 2, and thereafter the resultant was baked at 240° C. for 60 seconds and further baked at 400° C. for 120 seconds, to thereby produce each underlayer film having a thickness of 200 nm. The rate (%) of reduction in film thickness was calculated from the difference in film thickness before and after the baking at 400° C., to evaluate the heat resistance of such each underlayer film. The etching resistance was evaluated in the following conditions. The results are shown in Table 2.

[Measurement of Film Thickness]

The thickness of a resin film obtained from such each composition for film formation for lithography was measured with interference film thickness meter “OPTM-A1” (manufactured by Otsuka Electronics Co., Ltd.).

[Evaluation of Heat Resistance of Film]

The evaluation criteria were as follows.

S: Rate of reduction in film thickness before and after baking at 400° C.≤10%

A: Rate of reduction in film thickness before and after baking at 400° C.≤15%

B: Rate of reduction in film thickness before and after baking at 400° C.≤20%

C: Rate of reduction in film thickness before and after baking at 400° C.>20%

[Etching Test]

Etching apparatus: RIE-10NR manufactured by Samco Inc.

Output: 50 W

Pressure: 4 Pa

Time: 2 minutes

Etching gas

Flow rate of CF₄ gas: Flow rate of O₂ gas=5:15 (sccm)

[Evaluation of Etching Resistance]

Evaluation of etching resistance was performed according to the following procedure.

First, a novolak underlayer film was produced in the same conditions as those in Example 1 except that novolak (PSM4357 manufactured by Gunei Chemical Industry Co., Ltd.) was used instead of the film forming material for lithography in Example 1 and the drying temperature was 110° C. The above etching test was performed with this novolak underlayer film as a subject, and the etching rate here was measured.

Next, the above etching test was performed in the same manner with each of the underlayer films of Examples 1 to 15 and Comparative Examples 1 to 2, and the etching rate here was measured.

The etching rate of the novolak underlayer film was defined as a reference and the etching resistance was evaluated according to the following evaluation criteria. Rating S is particularly preferable, and Rating A and Rating B are preferable, from a practical viewpoint.

S: an etching rate relative to the novolak underlayer film, of less than −30%

A: an etching rate relative to the novolak underlayer film, of −30% or more and less than −20%

B: an etching rate relative to the novolak underlayer film, of −20% or more and less than −10%

C: an etching rate relative to the novolak underlayer film, of −10% or more and 0% or less

TABLE 2

| | | Crosslinking | | Heat | |
|---|---|---|---|---|---|
| | Resin (parts by | agent (parts by | Solvent (parts | resistance of | Etching |
| | mass) | mass) | by mass) | film | resistance |
| Example 1 | PBI-n(10) | — | DMSO(90) | S | S |
| Example 2 | Bz-PB1-n(10) | — | DMSO(90) | S | S |
| Example 3 | Et-PBI-n(10) | — | DMSO(90) | S | S |
| Example 4 | PBI-E(10) | — | DMSO(90) | S | S |
| Example 5 | Bz-PBI-E(10) | — | DMSO(90) | S | S |
| Example 6 | Et-PBI-E(10) | — | DMSO(90) | S | S |
| Example 7 | PBI-S(10) | — | DMSO(90) | S | S |
| Example 8 | Bz-PBI-S(10) | — | DMSO(90) | S | S |
| Example 9 | Et-PBI-S(10) | — | DMSO(90) | S | S |
| Example 10 | PBI-n(10) | NC-3000-L(2) | DMSO(90) | A | A |
| Example 11 | Et-PBI-n(10) | NC-3000-L(2) | DMSO(90) | A | A |
| Example 12 | PBI-E(10) | NC-3000-L(2) | DMSO(90) | A | A |
| Example 13 | Et-PBI-E(10) | NC-3000-L(2) | DMSO(90) | A | A |
| Example 14 | PBI-S(10) | NC-3000-L(2) | DMSO(90) | A | A |
| Example 15 | Et-PBI-S(10) | NC-3000-L(2) | DMSO(90) | A | A |
| Comparative | CR-1 | — | DMSO(90) | B | C |
| Example 1 | | | | | |
| Comparative | CR-1 | NC-3000-L(2) | DMSO(90) | C | C |
| Example 2 | | | | | |

### Example 16

A SiO₂ substrate having a thickness of 300 nm was coated with the composition for film formation for lithography obtained in Example 1, and baked at 240° C. for 60 seconds and further baked at 400° C. for 120 seconds, to thereby form an underlayer film having a thickness of 70 nm. The underlayer film was coated with a resist solution for ArF and baked at 130° C. for 60 seconds to thereby form a photoresist layer having a thickness of 140 nm. The resist solution for ArF here used was prepared by compounding 5 parts by mass of a compound of the following formula (22), 1 part by mass of triphenylsulfonium nonafluoromethanesulfonate, 2 parts by mass of tributylamine, and 92 parts by mass of PGMEA.

The compound of the following formula (22) was prepared as follows. Specifically, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to provide a solution. The solution was retained at a reaction temperature of 63° C. under a nitrogen atmosphere to allow polymerization to occur for 22 hours, and thereafter a reaction solution was dropped in 400 mL of n-hexane. A product resin thus obtained was solidified and purified, and a white powder produced was filtrated and dried at 40° C. under reduced pressure overnight, to thereby obtain a compound represented by the following formula.

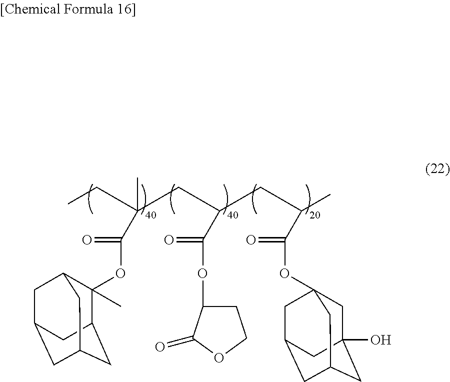

In the formula, 40, 40, and 20 are the ratios of respective constituent units, and are not intended to indicate that the polymer is a block copolymer.

Next, the photoresist layer was exposed with an electron beam lithography apparatus (ELS-7500 manufactured by Elionix Inc., 50 keV), baked (PEB) at 115° C. for 90 seconds, and developed by an aqueous 2.38 mass % tetramethylammonium hydroxide (TMAH) solution for 60 seconds, to thereby obtain a positive resist pattern. The evaluation results are shown in Table 3.

### Example 17

A positive resist pattern was obtained in the same manner as in Example 16 except that the composition for underlayer film formation for lithography in Example 2 was used instead of the composition for underlayer film formation for lithography in Example 1. The evaluation results are shown in Table 3.

### Example 18

A positive resist pattern was obtained in the same manner as in Example 16 except that the composition for underlayer film formation for lithography in Example 3 was used instead of the composition for underlayer film formation for lithography in Example 1. The evaluation results are shown in Table 3.

### Comparative Example 3

A positive resist pattern was obtained by forming a photoresist layer directly on a SiO₂ substrate in the same manner as in Example 16 except that no underlayer film was formed. The evaluation results are shown in Table 3.

### EVALUATION

Each of resist pattern shapes of 55 nmL/S (1:1) and 80 nmL/S (1:1), obtained in Examples 16 to 18 and Comparative Example 3, was observed with an electron microscope (S-4800) manufactured by Hitachi, Ltd. A resist pattern shape after development was evaluated, and one which had no pattern collapse and which was favorable in rectangularity was rated as favorable, and one different therefrom was rated as poor. As a result of the observation, a minimum line width at which no pattern collapse was caused and rectangularity was favorable was defined as resolution performance and adopted as an index of evaluation. Furthermore, a minimum amount of electron beam energy, at which a favorable pattern shape could be drawn, was defined as sensitivity and adopted as an index of evaluation.

TABLE 3

| | Composition | | | |
|---|---|---|---|---|
| | for film | Resolution | | Resist pattern |
| | formation for | performance | Sensitivity | shape after |
| | lithography | (nmL/S) | (μC/cm²) | development |
| Example 16 | Composition | 50 | 16 | Favorable |
| | obtained | | | |
| | in Example 1 | | | |
| Example 17 | Composition | 60 | 15 | Favorable |
| | obtained | | | |
| | in Example 2 | | | |
| Example 18 | Composition | 50 | 15 | Favorable |
| | obtained | | | |
| | in Example 3 | | | |
| Comparative | Not used | 90 | 42 | Poor |
| Example 3 | | | | |

As clear from Table 3, it was confirmed that Examples 16 to 18 each using the composition for film formation for lithography of the present embodiment were significantly excellent in both resolution performance and sensitivity as compared with Comparative Example 3. It was also been confirmed that the resist pattern shape after development also had no pattern collapse and was favorable in rectangularity. It was indicated from the difference in resist pattern shape after development that the respective underlayer films of Example 16 to 18, obtained from the compositions for film formation for lithography of Examples 1 to 3, had each good adhesion to a resist material.

### Example B1

A silicon substrate was spin coated with the composition for film formation for lithography prepared in Example 1, and baked at 150° C. for 60 seconds for film formation and solvent removal. Thereafter, heat resistance evaluation was performed with a lamp annealing furnace, as follows.

### Example B2 to Example B15 and Comparative Example B1 to Comparative Example B2

Each heat resistance evaluation was performed in the same manner as in Example B1 except that the composition for film formation for lithography, here used, was changed in compositional profile as shown in Table 4.

[Evaluation of High-Temperature Heat Resistance of Cured Film]

The substrate on which the film was formed was heated at 450° C. under a nitrogen atmosphere, and the rate of change in film thickness between 4 minutes and 10 minutes after the start of the heating was determined. The heating was continued at 550° C. under a nitrogen atmosphere, and the rate of change in film thickness between 4 minutes and 10 minutes after the start of the heating was determined. These rates of change in film thickness were each adopted as an index of heat resistance of a cured film, and evaluated. The respective film thicknesses before and after a heat resistance test were measured with an interference film thickness meter, and the rate of change in film thickness (percentage %), with the film thickness before a heat resistance test, as a reference, was defined as the value of variation in film thickness. The results are shown in Table 4.

TABLE 4

| | | Heat resistance of cured film, Rate | |
|---|---|---|---|
| | Composition for film | (%) of change in film thickness | |
| | formation for lithography | 450° C. | 550° C. |
| Example B1 | Composition obtained in | 2.3 | 5.4 |
| | Example 1 | | |
| Example B2 | Composition obtained in | 2.2 | 5.6 |
| | Example 2 | | |
| Example B3 | Composition obtained in | 2.5 | 6.1 |
| | Example 3 | | |
| Example B4 | Composition obtained in | 2.3 | 5.8 |
| | Example 4 | | |
| Example B5 | Composition obtained in | 2.1 | 5.5 |
| | Example 5 | | |
| Example B6 | Composition obtained in | 1.9 | 4.7 |
| | Example 6 | | |
| Example B7 | Composition obtained in | 2.0 | 5.1 |
| | Example 7 | | |
| Example B8 | Composition obtained in | 2.5 | 6.5 |
| | Example 8 | | |
| Example B9 | Composition obtained in | 2.6 | 6.8 |
| | Example 9 | | |
| Example B10 | Composition obtained in | 2.2 | 5.8 |
| | Example 10 | | |
| Example B11 | Composition obtained in | 2.3 | 6.1 |
| | Example 11 | | |
| Example B12 | Composition obtained in | 4.6 | 9.6 |
| | Example 12 | | |
| Example B13 | Composition obtained in | 4.3 | 8.8 |
| | Example 13 | | |
| Example B14 | Composition obtained in | 1.9 | 5.3 |
| | Example 14 | | |
| Example B15 | Composition obtained in | 1.5 | 4.8 |
| | Example 15 | | |
| Comparative | Composition obtained in | 35.8 | 61.2 |
| Example B1 | Comparative Example 1 | | |
| Comparative | Composition obtained in | 31.8 | 51.2 |
| Example B2 | Comparative Example 2 | | |

### Example C1

A 12-inch silicon wafer was subjected to a thermal oxidation treatment to thereby prepare a substrate having a silicon oxide film thereon, and a resin film having a thickness of 100 nm was produced thereon according to the same method with the composition for film formation for lithography of Example 1. A silicon oxide film and a SiN film were each formed on the resin film, as described below, and film formability by PE-CVD was evaluated.

### Example C2 to Example C15 and Comparative Example C1 to Comparative Example C2

Film formation was performed in the same manner as in Example C1 except that the composition for film formation for lithography, here used, was changed in compositional profile as shown in Table 5, and evaluation was performed.

[Evaluation of Silicon Oxide Film]

A silicon oxide film having a thickness of 70 nm was formed on the resin film at a substrate temperature of 300° C. with TEOS (tetraethylsiloxane) as a raw material by use of a film formation apparatus TELINDY (manufactured by Tokyo Electron Limited). A wafer provided with a cured film, on which such a silicon oxide film was laminated, was subjected to defect examination with KLA-Tencor SP-5, and the number of defects on the oxide film formed was evaluated with the number of defects of 21 nm or more, as an index.

A the number of defects s 20

B 20<the number of defects ≤50

C 50<the number of defects ≤100

D 100<the number of defects ≤1000

E 1000<the number of defects ≤5000

F 5000<the number of defects

[Evaluation of SiN Film]

According to the same method as described above, a substrate which had a silicon oxide film with a thickness of 100 nm obtained by a thermal oxidation treatment on a 12-inch silicon wafer was prepared, and then a cured film with was formed thereon. Furthermore a SiN film having a thickness of 40 nm, a refractive index of 1.94, and a stress of 54 MPa was formed thereon at a substrate temperature of 350° C. with SiN₄ (monosilane) and ammonia as raw materials by use of a film formation apparatus TELINDY (manufactured by Tokyo Electron Limited). Such a wafer provided with the cured film, on which the SiN film was laminated, was subjected to defect examination with KLA-Tencor SP-5, and the number of defects on the oxide film formed was evaluated with the number of defects of 21 nm or more, as an index, as described above. The results are shown in Table 5.

TABLE 5

| | Composition for film | Defect evaluation for PE-CVD | |
|---|---|---|---|
| | formation for lithography | Oxide film | SiN |
| Example C1 | Composition obtained in | B | B |
| | Example 1 | | |
| Example C2 | Composition obtained in | B | B |
| | Example 2 | | |
| Example C3 | Composition obtained in | B | B |
| | Example 3 | | |
| Example C4 | Composition obtained in | B | B |
| | Example 4 | | |
| Example C5 | Composition obtained in | B | B |
| | Example 5 | | |
| Example C6 | Composition obtained in | B | B |
| | Example 6 | | |
| Example C7 | Composition obtained in | B | B |
| | Example 7 | | |
| Example C8 | Composition obtained in | B | B |
| | Example 8 | | |
| Example C9 | Composition obtained in | B | B |
| | Example 9 | | |
| Example C10 | Composition obtained in | A | A |
| | Example 10 | | |
| Example C11 | Composition obtained in | A | A |
| | Example 11 | | |
| Example C12 | Composition obtained in | B | B |
| | Example 12 | | |
| Example C13 | Composition obtained in | B | B |
| | Example 13 | | |
| Example C14 | Composition obtained in | A | A |
| | Example 14 | | |
| Example C15 | Composition obtained in | A | A |
| | Example 15 | | |
| Comparative | Composition obtained in | F | F |
| Example C1 | Comparative Example 1 | | |
| Comparative | Composition obtained in | E | E |
| Example C2 | Comparative Example 2 | | |

The number of defects of 21 nm or more on the silicon oxide film or SiN film formed on each of the resin films of Examples C1 to C15 was 50 or less (Rating B or better), and was indicated to be decreased as compared with the number of defects in Comparative Example C1 or C2.

### Example D1

A silicon oxide film was formed on a 12-inch silicon wafer by a thermal oxidation treatment to prepare a substrate. On the substrate, a resin film having a thickness of 100 nm was produced by use of a solution of the composition for film formation for lithography of Example 1, according to the same method as in Example 1. The resin film was further subjected to an annealing treatment by heating in conditions of 600° C. and 4 minutes on a hot plate on which a high temperature-treatment was possible, under a nitrogen atmosphere, and a wafer on which the resin film annealed was laminated was produced. The substrate was subjected to etching evaluation as described below.

[Evaluation of Etching after High-Temperature Treatment]

The substrate was subjected to each etching treatment in a condition of use of CF₄/Ar as an etching gas and in a condition of use of Cl₂/Ar as an etching gas by use of an etching apparatus TELIUS (manufactured by Tokyo Electron Limited), and the etching rate was evaluated. Such evaluation of the etching rate was made by using a resin film having a thickness of 200 nm, produced by an annealing treatment of SU8 (manufactured by Nippon Kayaku Co., Ltd.) at 250° C. for 1 minute, as a reference, and determining the ratio of the etching rate to the etching rate of such SU8, as a relative value.

### Example D2 to Example D15 and Comparative Example D1 to Comparative Example D2

Etching evaluation after a high temperature treatment was performed in the same manner as in Example D1 except that the composition for film formation for lithography, here used, was changed in compositional profile as shown in Table 6.

TABLE 6

| | | Evaluation of etching rate | |
|---|---|---|---|
| | Composition for film | (relative value) | |
| | formation for lithography | CF₄/Ar | Cl₂/Ar |
| Example D1 | Composition obtained in | 0.82 | 0.81 |
| | Example 1 | | |
| Example D2 | Composition obtained in | 0.83 | 0.83 |
| | Example 2 | | |
| Example D3 | Composition obtained in | 0.80 | 0.82 |
| | Example 3 | | |
| Example D4 | Composition obtained in | 0.79 | 0.82 |
| | Example 4 | | |
| Example D5 | Composition obtained in | 0.81 | 0.80 |
| | Example 5 | | |
| Example D6 | Composition obtained in | 0.82 | 0.82 |
| | Example 6 | | |
| Example D7 | Composition obtained in | 0.82 | 0.83 |
| | Example 7 | | |
| Example D8 | Composition obtained in | 0.78 | 0.79 |
| | Example 8 | | |
| Example D9 | Composition obtained in | 0.78 | 0.79 |
| | Example 9 | | |
| Example D10 | Composition obtained in | 0.83 | 0.77 |
| | Example 10 | | |
| Example D11 | Composition obtained in | 0.81 | 0.80 |
| | Example 11 | | |
| Example D12 | Composition obtained in | 0.74 | 0.77 |
| | Example 12 | | |
| Example D13 | Composition obtained in | 0.76 | 0.77 |
| | Example 13 | | |
| Example D14 | Composition obtained in | 0.72 | 0.73 |
| | Example 14 | | |
| Example D15 | Composition obtained in | 0.71 | 0.72 |
| | Example 15 | | |
| Comparative | Composition obtained in | 0.98 | 0.98 |
| Example D1 | Comparative Example 1 | | |
| Comparative | Composition obtained in | 0.95 | 0.95 |
| Example D2 | Comparative Example 2 | | |

### <Example E1> Purification of Et-PBI-n Resin by Acid

A four-necked flask (detachable bottom) having a volume of 1000 ml, was charged with 150 g of a solution (10 mass %) in which the Et-PBI-n resin obtained in Synthesis Example 1-2 was dissolved in cyclohexanone (CHN), and the resultant was heated to 80° C. with stirring. Next, 37.5 g of an aqueous oxalic acid solution (pH 1.3) was added and the resultant was stirred for 5 minutes and thereafter left to still stand for 30 minutes. The system was thus separated to an oil phase and an aqueous phase, and the aqueous phase was removed. Such an operation was repeated once, thereafter the oil phase obtained was charged with 37.5 g of ultrapure water, and the resultant was stirred for 5 minutes and thereafter left to still stand for 30 minutes to thereby remove the aqueous phase. Such an operation was repeated three times, thereafter the inside of the flask was depressurized to 200 hPa or less with heating to 80° C. and thus the remaining moisture and CHN were distilled off by concentration. Thereafter, the resultant was diluted with CHN (EL grade) (reagent manufactured by Kanto Chemical Co., Inc.) and the concentration was adjusted to 10 mass %, to thereby obtain a solution of the Et-PBI-n resin in CHN, in which the metal content was decreased. Such a resin solution was filtrated in a condition of 0.5 MPa by a UPE filter having a nominal pore size of 3 nm, manufactured by Entegris Japan Co., Ltd., to thereby obtain a solution sample. The solution sample was used to perform etching defect evaluation on a laminated film, as described below.

[Etching Defect Evaluation on Laminated Film]

Quality evaluation of a laminated film with a purification treatment of a composition was performed. Specifically, a film of the composition for film formation for lithography was formed on a wafer and the film was etched and features thereof were reflected toward a substrate, and thereafter defect evaluation was performed. The evaluation was performed specifically as follows.

(Substrate with Si Oxide Film Formed Thereon)

A 12-inch silicon wafer was subjected to a thermal oxidation treatment, to thereby obtain a substrate having a silicon oxide film having a thickness of 100 nm. A film was formed on the substrate by the solution of the composition for film formation for lithography, which had been purified, by adjusting conditions of spin coating so that the thickness was 100 nm, and thereafter baked at 150° C. for 1 minutes and subsequently baked at 350° C. for 1 minutes, to thereby produce a laminated substrate where an underlayer film for lithography was laminated on silicon provided with a thermally oxidized film. TELIUS (manufactured by Tokyo Electron Limited) was used as an etching apparatus, and the underlayer film for lithography was etched in a condition of CF₄/O₂/Ar to expose the surface of the oxide film of the substrate. The oxide film further was subjected to an etching treatment in a condition of etching of 100 nm with a gas at a compositional ratio of CF₄/Ar, to thereby produce a wafer etched. The number of defects of 19 nm or more on the wafer etched was measured with a defect examination apparatus SP5 (manufactured by KLA-Tencor Corporation). The evaluation criteria were as described above.

(Substrate with SiN Film Formed Thereon)

A substrate having a silicon oxide film with a thickness of 100 nm formed by thermal oxidation treatment on a 12-inch silicon wafer was prepared. On the substrate, a SiN film having a thickness of 40 nm, a refractive index of 1.94, and a stress of 54 MPa was formed by SiN₄ (monosilane) and ammonia as raw materials in use of a film formation apparatus TELINDY (manufactured by Tokyo Electron Limited) at a substrate temperature of 350° C. An underlayer film for lithography was formed on the substrate in the same manner as described above, and subjected to an etching treatment in the same conditions, to thereby produce a wafer etched. The number of defects of 19 nm or more on the wafer etched was measured with a defect examination apparatus SP5 (manufactured by KLA-Tencor). The evaluation criteria were as described above.

### <Example E2> Purification by Liquid Passing Through Filter

A four-necked flask (detachable bottom) having a volume of 1000 mL was charged with 500 g of a solution having a concentration of 10 mass %, in which the Et-PBI-n resin obtained in Synthesis Example 1-2 was dissolved in cyclohexanone (CHN), in a class 1000 clean booth. Subsequently, the air in the flask was removed under reduced pressure, thereafter a nitrogen gas was introduced thereinto to thereby return the pressure to an ambient pressure, the oxygen concentration in the inside was adjusted to less than 1% with nitrogen gas passing at 100 mL per minute, and thereafter heating to 30° C. was made with stirring. The solution was drained through a valve for detaching a bottom, and allowed to go through a pressure-resistant tube made of a fluororesin and pass through a nylon hollow fiber membrane filter (manufactured by Kitz Microfilter Corporation, trade name: Polyfix nylon series) having a nominal pore size of 0.01 μm in a condition so that the filtration pressure was 0.5 MPa, and thus filtration under pressure was made. The solution was here allowed to pass through with a diaphragm pump at a flow rate of 100 mL/min. The resin solution after filtration was diluted with CHN (EL grade) (reagent manufactured by Kanto Chemical Co., Inc.) and the concentration was adjusted to 10 mass %, to thereby obtain a solution of the Et-PBI-n resin in CHN, in which the metal content was decreased. Such a resin solution was filtrated in a condition of 0.5 MPa by a UPE filter having a nominal pore size of 3 nm, manufactured by Entegris Japan Co., Ltd., to thereby obtain a solution sample. The solution sample was used to perform etching defect evaluation on a laminated film. The oxygen concentration was measured with an oxygen concentration meter “OM-25MF10” manufactured by ASONE Corporation (the same applies hereinafter).

### Example E3

IONKLEEN manufactured by Pall Corporation, a nylon filter manufactured by Pall Corporation, and furthermore a UPE filter having a nominal pore size of 3 nm, manufactured by Entegris Japan Co., Ltd., were connected in series in the listed order, to thereby construct a filter line. Filtration under pressure was performed in the same manner as in Example E2 except that the filter line was used instead of the nylon hollow fiber membrane filter of 0.01 μm. The resultant was diluted with CHN (EL grade) (reagent manufactured by Kanto Chemical Co., Inc.) and the concentration was adjusted to 10 mass %, to thereby obtain a solution of the Et-PBI-n resin in CHN, in which the metal content was decreased. The solution was filtrated under pressure in a condition so that the filtration pressure was 0.5 MPa, by a UPE filter having a nominal pore size of 3 nm, manufactured by Entegris Japan Co., Ltd., to thereby obtain a solution sample. The solution sample was used to perform etching defect evaluation on a laminated film.

### Example E4

The solution sample produced in Example E1 was further filtrated under pressure with the filter line produced in Example E3 in a condition so that the filtration pressure was 0.5 MPa, to thereby obtain a solution sample. The solution sample was used to perform etching defect evaluation on a laminated film.

### Example E5

The Et-PBI-E produced in Synthesis Example 2-2 was purified by the same method as in Example E1, to thereby obtain a solution sample. The solution sample was used to perform etching defect evaluation on a laminated film.

### Example E6

The Et-PBI-S produced in Synthesis Example 3-2 was purified by the same method as in Example E1, to thereby obtain a solution sample. The solution sample was used to perform etching defect evaluation on a laminated film.

TABLE 7

| | | Defect evaluation for PE-CVD | |
|---|---|---|---|
| | | Silicon oxide | |
| | Resin used | film | SiN film |
| Example E1 | Et-PBI-n | A | A |
| Example E2 | Et-PBI-n | A | A |
| Example E3 | Et-PBI-n | A | A |
| Example E4 | Et-PBI-n | A | A |
| Example E5 | Et-PBI-E | A | A |
| Example E6 | Et-PBI-S | A | A |

### INDUSTRIAL APPLICABILITY

The film forming material for lithography of the present embodiment has relatively high heat resistance and also relatively high solvent-solubility, and has excellent embedding properties to a substrate having difference in level, as well as film flatness, and can be applied to a wet process. Thus, a composition for film formation for lithography, including the film forming material for lithography, can be widely and effectively used in various applications where such performances are required. In particular, the present invention can be particularly effectively used in the fields of an underlayer film for lithography and an underlayer film for a multi-layer resist.

1. A film forming material for lithography, comprising a resin having a polybenzimidazole structure represented by the following formula (1): 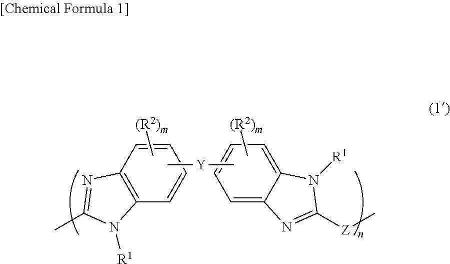
wherein
Y and Z are each a single bond; a divalent linking group comprising a chalcogen atom; and a divalent linking group derived from a compound selected from the group consisting of an aromatic compound, a linear, branched or cyclic aliphatic compound, and a heterocyclic compound,
R¹ is each independently a hydrogen atom, or a substituent T selected from the group consisting an alkyl group having 1 to 30 carbon atoms and optionally having a substituent, an aryl group having 6 to 40 carbon atoms and optionally having a substituent, an aralkyl group having 7 to 40 carbon atoms and optionally having a substituent, an alkenyl group having 2 to 30 carbon atoms and optionally having a substituent, an alkynyl group having 2 to 30 carbon atoms and optionally having a substituent, an arylalkenyl group having 7 to 40 carbon atoms and optionally having a substituent, an alkoxy group having 1 to 30 carbon atoms and optionally having a substituent, a halogen atom, a nitro group, an amino group, a cyano group, a carboxylic acid group, a thiol group and a hydroxy group, wherein the aryl group, the aralkyl group, the alkenyl group, the alkynyl group and the arylalkenyl group each optionally comprise an ether bond, a ketone bond, an ester bond or a urethane bond,
R² is each independently the substituent T,
m is an integer of 0 to 3, and
n is an integer of 1 to 10000.

2. The film forming material for lithography according to claim 1, wherein R¹ in the formula is a group other than a hydrogen atom.

3. The film forming material for lithography according to claim 1, wherein Y is a single bond, —O—, —S—, —CH₂—, —C(CH₃)₂—, —CO—, —SO₂—, —C(CF₃)₂—, —CONH— or —COO—.

4. The film forming material for lithography according to claim 3, wherein Y is a single bond.

5. The film forming material for lithography according to claim 1, wherein the film for lithography is an underlayer film for lithography.

6. A composition for film formation for lithography, comprising the film forming material for lithography according to claim 1, and a solvent.

7. The composition for film formation for lithography according to claim 6, further comprising a crosslinking agent, a crosslinking promoting agent, a radical polymerization initiator, an acid generating agent or a combination thereof.

8. An underlayer film for lithography, formed using the composition for film formation for lithography according to claim 6.

9. A method for forming a resist pattern, comprising
a step of forming an underlayer film on a substrate using the composition for film formation for lithography according to claim 6,
a step of forming at least one photoresist layer on the underlayer film, and
a step of irradiating a predetermined region of the photoresist layer with radiation for development.

10. A method for forming a pattern, comprising
a step of forming an underlayer film on a substrate using the composition for film formation for lithography according to claim 6,
a step of forming an intermediate layer film on the underlayer film using a silicon atom-containing resist intermediate layer film material,
a step of forming at least one photoresist layer on the intermediate layer film,
a step of irradiating a predetermined region of the photoresist layer with radiation for development to thereby form a resist pattern,
a step of etching the intermediate layer film with the resist pattern as a mask,
a step of etching the underlayer film with an intermediate layer film pattern obtained in the above step, as an etching mask, and
a step of etching the substrate with an underlayer film pattern obtained, as an etching mask, to thereby form a pattern on the substrate.

11. A method for purifying the film forming material for lithography according to claim 1, comprising
a step of dissolving the film forming material for lithography in a solvent to thereby obtain an organic phase, and
a first extraction step of contacting the organic phase and an acidic aqueous solution to thereby extract impurities in the film forming material for lithography, wherein
the solvent comprises a solvent that does not mix with water at any ratio.

12. A resin having a polybenzimidazole structure represented by the following formula (1′): 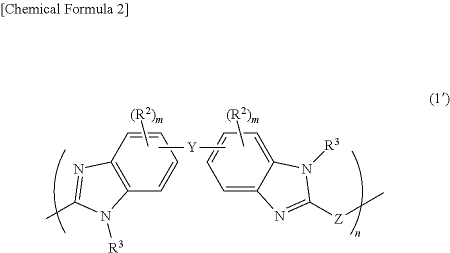
wherein
Y and Z are each a single bond, a divalent linking group comprising a chalcogen atom, or a divalent linking group derived from a compound selected from the group consisting of an aromatic compound, a linear, branched or cyclic aliphatic compound, and a heterocyclic compound,
R³ is each independently a substituent T selected from the group consisting an alkyl group having 1 to 30 carbon atoms and optionally having a substituent, an aryl group having 6 to 40 carbon atoms and optionally having a substituent, an aralkyl group having 7 to 40 carbon atoms and optionally having a substituent, an alkenyl group having 2 to 30 carbon atoms and optionally having a substituent, an alkynyl group having 2 to 30 carbon atoms and optionally having a substituent, an arylalkenyl group having 7 to 40 carbon atoms and optionally having a substituent, an alkoxy group having 1 to 30 carbon atoms and optionally having a substituent, a halogen atom, a nitro group, an amino group, a cyano group, a carboxylic acid group, a thiol group and hydroxy group, wherein the aryl group, the aralkyl group, the alkenyl group, the alkynyl group and the arylalkenyl group each optionally comprise an ether bond, a ketone bond, an ester bond or a urethane bond,
R² is each independently the substituent T,
m is an integer of 0 to 3, and
n is an integer of 1 to 10000.

13. A method for producing a film for lithography, comprising
a step of preparing a composition including a resin having a polybenzimidazole structure, and
a step of placing the composition on a substrate and baking the resultant at 300 to 900° C.
